(19) United States
(12) Patent Application Publication
(10) Pub. No.: US 2025/0056799 A1
(43) Pub. Date: Feb. 13, 2025

(54) SEMICONDUCTOR MEMORY DEVICE, AND SEMICONDUCTOR PACKAGE AND ELECTRONIC SYSTEM INCLUDING THE SAME

(71) Applicant: Samsung Electronics Co., Ltd., Suwon-si (KR)

(72) Inventors: Kumhyo Kang, Suwon-si (KR); Hongsoo Kim, Suwon-si (KR); Jeon Il Lee, Suwon-si (KR); Hyun-Mook Choi, Suwon-si (KR)

(21) Appl. No.: 18/596,764

(22) Filed: Mar. 6, 2024

(30) Foreign Application Priority Data
Aug. 7, 2023 (KR) 10-2023-0103094

(51) Int. Cl. H10B 43/27; H10B 41/27; H10B 41/41; H10B 43/40

(52) U.S. Cl. CPC H10B 43/27; H10B 41/27; H10B 41/41; H10B 43/40

(57) ABSTRACT

A semiconductor memory device, and a semiconductor package and an electronic system including the same are provided. The semiconductor memory device includes a substrate including a plurality of mat regions and a mat separation region between ones of the mat regions, a peripheral circuit structure on the substrate and including peripheral circuits, a cell array structure on the peripheral circuit structure, a first through-via extending into the substrate in the mat separation region, and a second through-via extending into the cell array structure on the mat separation region and electrically connected to the first through-via, wherein the second through-via overlaps the first through-via.

### CROSS-REFERENCE TO RELATED APPLICATION(S)

This U.S. non-provisional patent application claims priority under 35 U.S.C. § 119 to Korean Patent Application No. 10-2023-0103094, filed on Aug. 7, 2023, in the Korean Intellectual Property Office, the entire contents of which are hereby incorporated by reference.

### BACKGROUND

The inventive concepts relate to a semiconductor memory device, and a semiconductor package and an electronic system including the same.

Semiconductor devices may be highly integrated for satisfying high performance and low manufacturing costs. Because integration of the semiconductor devices may be an important factor in determining product price, high integration is increasingly requested. Integration of typical two-dimensional or planar semiconductor memory devices may be primarily determined by the region occupied by a unit memory cell, such that it may be greatly influenced by the level of technology for forming fine patterns. However, the processing equipment needed to increase pattern fineness is extremely expensive, which may set a practical limitation on increasing the integration of the two-dimensional or planar semiconductor memory devices. Therefore, three-dimensional semiconductor memory devices having three-dimensionally arranged memory cells have been proposed.

### SUMMARY

An object of the inventive concepts is to provide a highly integrated semiconductor memory device.

An object of the inventive concepts is to provide a highly integrated semiconductor package with improved operating speed.

An object of the inventive concepts is to provide a highly integrated electronic system.

The problems to be solved by the inventive concepts are not limited to the problems mentioned above, and other problems not mentioned will be more clearly understood by those skilled in the art from the description below.

A semiconductor memory device according to some embodiments of the inventive concepts includes a substrate including a plurality of mat regions and a mat separation region between ones of the mat regions, a peripheral circuit structure on the substrate and including peripheral circuits, a cell array structure on the peripheral circuit structure, a first through-via extending into the substrate in the mat separation region, and a second through-via extending into the cell array structure on the mat separation region and electrically connected to the first through-via, wherein the second through-via overlaps the first through-via in a plan view.

A semiconductor package according to some embodiments of the inventive concepts includes a package substrate, semiconductor dies sequentially stacked on the package substrate, and a mold layer on side surfaces of the semiconductor dies and an upper surface of the package substrate, wherein each of the semiconductor dies includes a substrate including a plurality of mat regions and a mat separation region between ones of the mat regions, a peripheral circuit structure on the substrate and including peripheral circuits, a cell array structure on the peripheral circuit structure, a first through-via extending into the substrate in the mat separation region, a first input/output pad on a lower surface of the first through-via, a second through-via extending into the cell array structure on the mat separation region and electrically connected to the first through-via, and a second input/output pad on the second through-via, wherein the second through-via overlaps the first through-via, wherein the second input/output pad of a first one of the semiconductor dies is in contact with the first input/output pad of a second one of the semiconductor dies, and wherein the second one of the semiconductor dies is on the first one of the semiconductor dies.

An electronic system according to some embodiments of the inventive concepts includes a semiconductor memory device, and a controller electrically connected to the semiconductor memory device through an input/output pad and configured to control the semiconductor memory device, wherein the semiconductor memory device includes a substrate including a plurality of mat regions and a mat separation region between ones of the mat regions, a peripheral circuit structure on the substrate and including peripheral circuits, a cell array structure on the peripheral circuit structure, a first through-via extending into the substrate in the mat separation region, and a second through-via extending into the cell array structure on the mat separation region and electrically connected to the first through-via, and wherein the second through-via overlaps the first through-via.

### BRIEF DESCRIPTION OF THE DRAWINGS

Example embodiments will be more clearly understood from the following description taken in conjunction with the accompanying drawings. The accompanying drawings represent non-limiting, example embodiments as described herein.

FIG. 1A is a diagram schematically illustrating an electronic system including a semiconductor device according to some embodiments of the inventive concepts.

FIG. 1B is a perspective view schematically illustrating an electronic system including a semiconductor device according to some embodiments of the inventive concepts.

FIG. 2A is a schematic plan view of a semiconductor memory device according to some embodiments of the inventive concepts.

FIG. 2B is a detailed plan view of a semiconductor memory device according to some embodiments of the inventive concepts.

FIG. 3 is a schematic perspective view of a semiconductor memory device according to some embodiments of the inventive concepts.

FIG. 4 is an enlarged view of portion ‘P1’ of FIG. 2B.

FIG. 5A is an enlarged view of portion ‘P2’ of FIG. 4.

FIG. 5B is an enlarged view of portion ‘P3’ of FIG. 4.

FIGS. 6A to 6D are cross-sectional views taken along line A-A′ of FIG. 5A according to some embodiments of the inventive concepts.

FIG. 7 is a cross-sectional view taken along line B-B′ of FIG. 5B according to some embodiments of the inventive concepts.

FIG. 8 is a cross-sectional view taken along line C-C′ of FIG. 5B according to some embodiments of the inventive concepts.

FIG. 9 is an enlarged view of portion ‘P4’ of FIG. 7.

FIGS. 10A to 10H are cross-sectional views sequentially illustrating a process of manufacturing the semiconductor memory device of FIG. 6A.

FIG. 11A is a cross-sectional view taken along line A-A′ of FIG. 5A according to some embodiments of the inventive concepts.

FIG. 11B is a cross-sectional view taken along line B-B′ of FIG. 5B according to some embodiments of the inventive concepts.

FIG. 11C is a cross-sectional view taken along line C-C′ of FIG. 5B according to some embodiments of the inventive concepts.

FIGS. 12A to 12E are diagrams illustrating a process of manufacturing the semiconductor memory device of FIG. 11A.

FIG. 13 is a plan view of a semiconductor memory device according to some embodiments of the inventive concepts.

FIG. 14 is a plan view of a semiconductor memory device according to some embodiments of the inventive concepts.

FIG. 15 is a plan view of a semiconductor memory device according to some embodiments of the inventive concepts.

FIG. 16 is an enlarged perspective view of portion ‘P5’ of FIG. 15.

FIG. 17 is a cross-sectional view of a semiconductor package according to some embodiments of the inventive concepts.

FIG. 18 is a cross-sectional view of a semiconductor package according to some embodiments of the inventive concepts.

FIG. 19 is a cross-sectional view of a semiconductor package according to some embodiments of the inventive concepts.

FIG. 20 is a cross-sectional view of a semiconductor package according to some embodiments of the inventive concepts.

### DETAILED DESCRIPTION

Hereinafter, to explain the inventive concepts in detail, example embodiments according to the inventive concepts will be described with reference to the accompanying drawings.

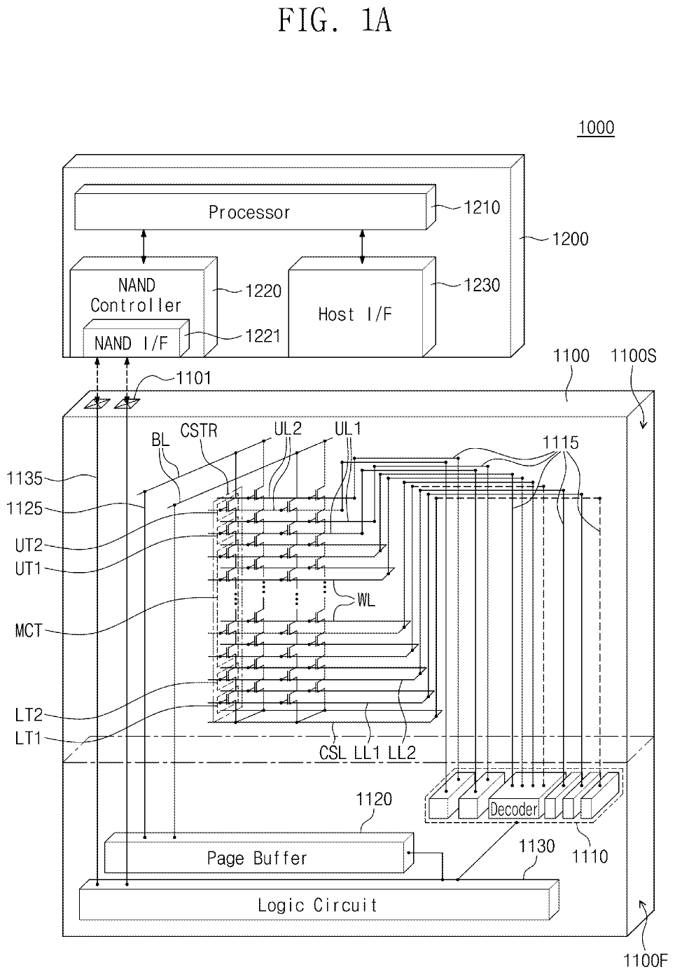

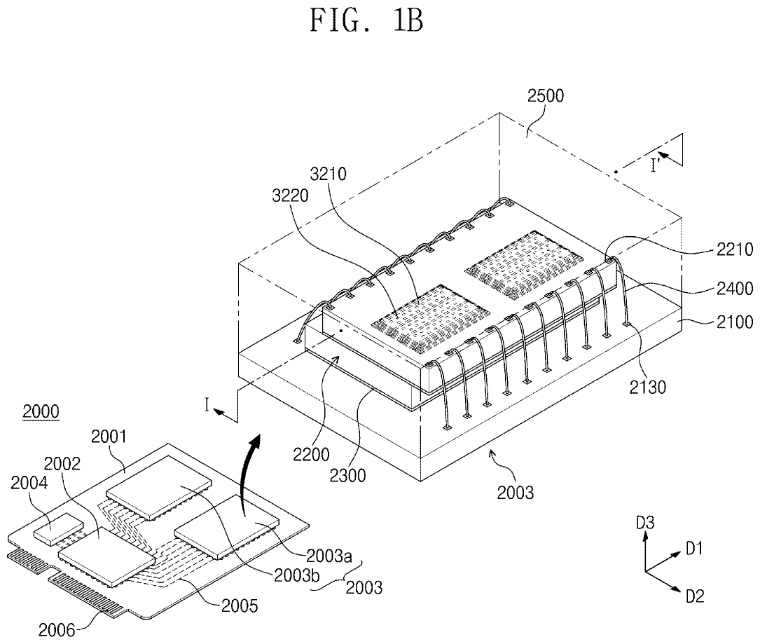

FIG. 1A is a diagram schematically illustrating an electronic system including a semiconductor device according to some embodiments of the inventive concepts.

Referring to FIG. 1A, an electronic system 1000 according to some embodiments of the inventive concepts may include a semiconductor device 1100 and a controller 1200, which are electrically connected to each other. The electronic system 1000 may be or may include a storage device including one or more semiconductor devices 1100 and/or an electronic device including the storage device. For example, the electronic system 1000 may be or may include at least one of a solid state drive (SSD) device, a universal serial bus (USB), a computing system, a medical system, or a communication system, in which at least one semiconductor device 1100 is provided.

The semiconductor device 1100 may be a nonvolatile memory device, and for example may be a three-dimensional NAND flash memory device. The semiconductor memory device 1100 may include a first structure 1100F and a second structure 1100S on the first structure 1100F. According to some embodiments, the first structure 1100F alternatively may be disposed at a side of the second structure 1100S. The first structure 1100F may be a peripheral circuit region, which includes a decoder circuit 1110, a page buffer 1120, and a logic circuit 1130. The second structure 1100S may be a memory cell region, which includes bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to various embodiments.

In embodiments, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cell transistors MCT, and the gate upper lines UL1 and UL2 may be respectively used as gate electrodes of the upper transistors UT1 and UT2.

In embodiments, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used to perform an erase operation, in which a gate-induced drain leakage (GIDL) phenomenon is used to erase/zero-out data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F into the second structure 1100S. The bit lines BL may be electrically connected to the page buffer 1120 through second connection lines 1125, which extend from the first structure 1100F into the second structure 1100S.

In the first structure 1100F, the decoder circuit 1110 and the page buffer 1120 may be configured to control a control operation, which is performed on at least one of the memory cell transistors MCT by a selection memory cell transistor. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is provided in the first structure 1100F and extends into the second structure 1100S.

The controller 1200 may include a processor 1210, a NAND controller 1220, and a host interface 1230. In some embodiments, the electronic system 1000 may include a plurality of semiconductor devices 1100, and in this case, the controller 1200 may control the semiconductor devices 1100.

The processor 1210 may control overall operations the electronic system 1000 including the controller 1200. The processor 1210 may be operated based on a specific firmware and/or software and/or hardware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands to control the semiconductor device 1100, and/or data to be written in or read from the memory cell transistors MCT of the semiconductor device 1100, and/or so forth. The host interface 1230 may be configured to allow for communication between the electronic system 1000 and an external host. When a control command is received from an external host through the host interface 1230, the processor 1210 may control the semiconductor device 1100 in response to the control command.

FIG. 1B is a perspective view schematically illustrating an electronic system including a semiconductor device according to some embodiments of the inventive concepts.

Referring to FIG. 1B, an electronic system 2000 according to some embodiments of the inventive concepts may include a main board 2001 and a controller 2002, at least one semiconductor package 2003, and a DRAM 2004, which are mounted on the main board 2001. The semiconductor package 2003 and the DRAM 2004 may be connected to the controller 2002 and to each other by interconnection patterns 2005, which are formed in the main board 2001.

The main board 2001 may include a connector 2006, which includes a plurality of pins coupled to an external host. In the connector 2006, the number and/or the arrangement of the pins may depend on a communication interface between the electronic system 2000 and the external host. In some embodiments, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In some embodiments, the electronic system 2000 may be driven by a power, which is supplied from the external host through the connector 2006. The electronic system 2000 may further include a power management integrated circuit (PMIC) distributing a power (not illustrated), which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be or may include a buffer memory, which relieves or helps to relieve technical difficulties caused by a difference in speed between the semiconductor package 2003, which serves as a data storage device, and an external host. In some embodiments, the DRAM 2004 in the electronic system 2000 may serve as a cache memory and may provide a storage space to temporarily store data during a control operation on the semiconductor package 2003. When the electronic system 2000 includes the DRAM 2004, the controller 2002 may further include a DRAM controller in order to control the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective lower surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be or may include a printed circuit board including package upper pads 2130. Each of the semiconductor chips 2200 may include an input/output pad 2210. The input/output pad 2210 may correspond to the input/output pad 1101 of FIG. 1A. Each of the semiconductor chips 2200 may include gate stacks 3210 and vertical structures 3220. Each of the semiconductor chips 2200 may include a semiconductor device, which will be described below, according to some embodiments of inventive concepts.

In embodiments, the connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. According to some other embodiments, the semiconductor chips 2200 in each of the first and second semiconductor packages 2003a and 2003b may be electrically connected to each other by a connection structure including through silicon vias (TSV), not by the connection structure 2400 provided in the form of bonding wires.

In embodiments, the controller 2002 and the semiconductor chips 2200 may be included in a single package. In some embodiments, the controller 2002 and the semiconductor chips 2200 may be mounted on a separate interposer substrate, which is prepared regardless of the main board 2001, and may be connected to each other through interconnection lines, which are provided in the interposer substrate.

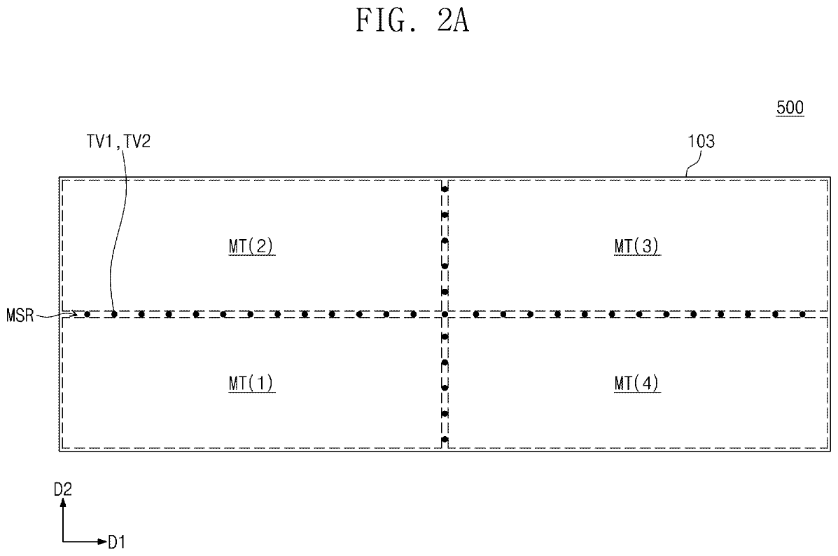

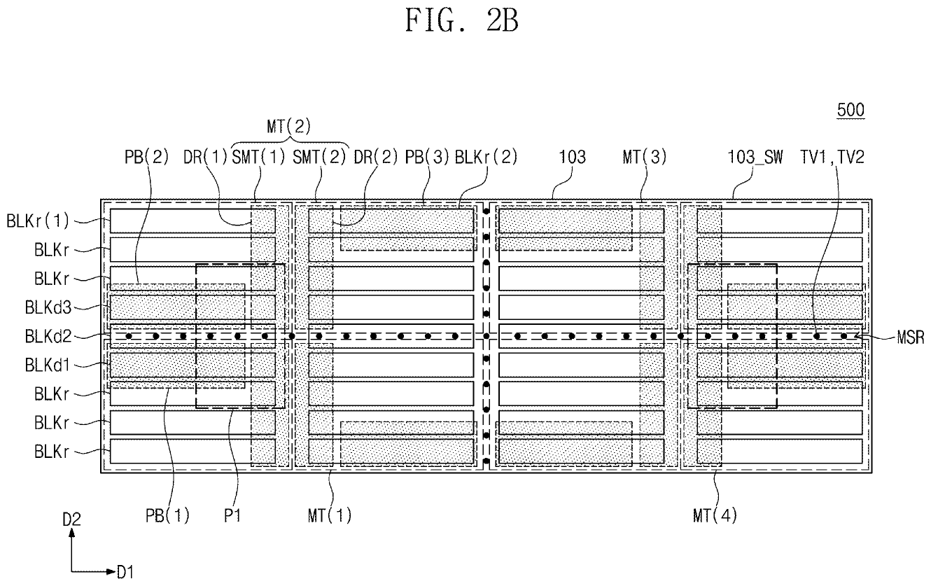

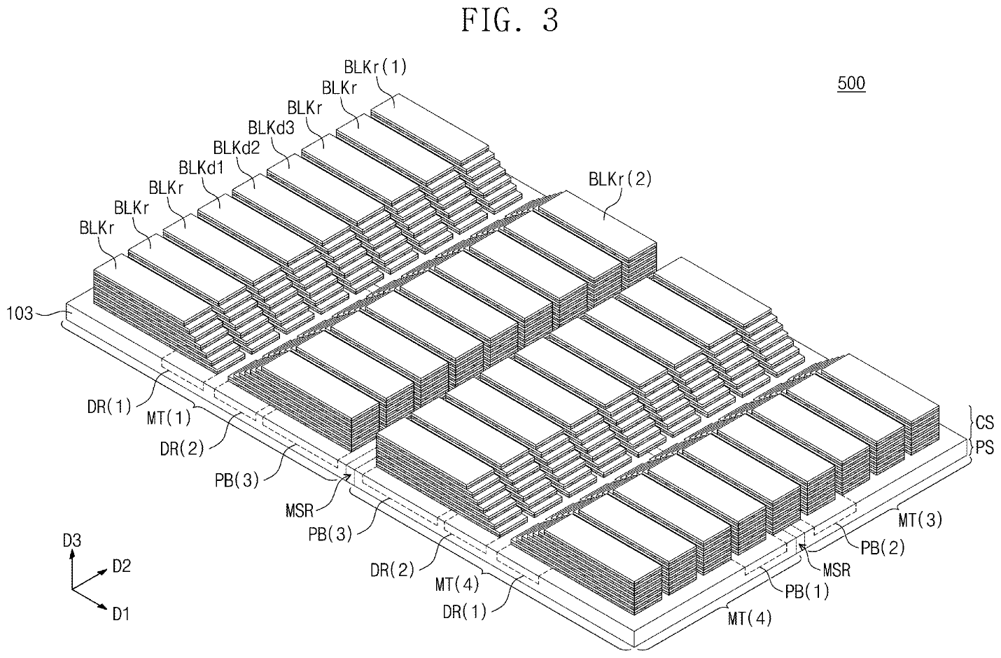

FIG. 2A is a schematic plan view of a semiconductor memory device according to some embodiments of the inventive concepts. FIG. 2B is a detailed plan view of a semiconductor memory device according to some embodiments of the inventive concepts. FIG. 3 is a schematic perspective view of a semiconductor memory device according to some embodiments of the inventive concepts.

Referring to FIGS. 2A, 2B, and 3, a semiconductor memory device 500 according to the inventive concepts includes a substrate 103. The substrate 103 includes a plurality of mat regions MT and a mat separation region MSR therebetween. That is, the mat separation region MSR may be between ones of the mat regions MT. A portion of a cell array structure CS disposed on the mat region MT may also be referred to as a bank. In this example, the mat regions MT may include first to fourth mat regions MT(1) to MT(4) arranged clockwise as illustrated in FIG. 2A. The first and second mat regions MT(1) and MT(2) may be arranged side by side in a second direction D2. That is, the first and second mat regions MT(1) and MT(2) may be adjacent to each other in the second direction D2. The second and third mat regions MT(2) and MT(3) may be arranged side by side in a first direction D1 that intersects the second direction D2. That is, the second and third mat regions MT(2) and MT(3) may be adjacent to each other in the first direction D1. Each mat region MT may include a first sub-mat region SMT(1) and a second sub-mat region SMT(2). The mat separation region MSR may have a cross shape when viewed in a plan view.

A peripheral circuit structure PS is disposed on the substrate 103. The cell array structure CS is disposed on the peripheral circuit structure PS. Through-vias TV1 and TV2 may be disposed in the mat separation region MSR. The through-vias TV1 and TV2 may include first through-vias TV1 and second through-vias TV2. The second through-vias TV2 may be disposed on the first through-vias TV1 and may overlap each other. The first through-vias TV1 may penetrate (i.e., extend into) the substrate 103 and the peripheral circuit structure PS. The second through-vias TV2 may penetrate (i.e., extend into) the cell array structure CS.

The peripheral circuit structure PS may include page buffer regions PB and decoder regions DR. The page buffer circuits (e.g., the page buffer circuit 1120 of FIG. 1A) for applying voltage to bit lines BLL of the cell array structure CS may be disposed in the page buffer regions PB. X-decoder circuits (e.g., the decoder circuit 1110 in FIG. 1A) for applying voltage to electrode layers EL1 and EL2 of the cell array structure CS may be disposed in the decoder regions DR.

The page buffer regions PB may include first to third page buffer regions PB(1) to PB(3). The decoder regions DR may include first and second decoder regions DR(1) and DR(2). The first page buffer region PB(1) and the first decoder region DR(1) may be disposed on a first sub-mat region SMT(1) of the first mat region MT(1). The second page buffer region PB(2) and the first decoder region DR(1) may be disposed on a first sub-mat region SMT(1) of the second mat region MT(2). The mat separation region MSR may be disposed between the first page buffer region PB(1) and the second page buffer region PB(2), which are adjacent to each other. The mat separation region MSR may be disposed between adjacent first decoder regions DR(1). The third page buffer region PB(3) and the second decoder region DR(2) may be disposed on the second sub-mat region SMT(2) of the second mat region MT(2). The third page buffer region PB(3) may be adjacent to a sidewall 103_SW of the substrate 103.

A structure of the peripheral circuit structure PS on the first mat region MT(1) may have a mirror symmetrical shape with a structure of the peripheral circuit structure PS on the second mat region MT(2). A structure of the peripheral circuit structure PS on the second mat region MT(2) may have a mirror symmetrical shape with a structure of the peripheral circuit structure PS on the third mat region MT(3).

The cell array structure CS may include a plurality of blocks BLKr, BLKd1 to BLKd3. The blocks BLKr, BLKd1 to BLKd3 may be arranged to be spaced apart from each other in the second direction D2 on the first and second sub-mat regions SMT(1) and SMT(2), respectively, and may be elongated in the first direction D1. The blocks BLKr and BLKd1 to BLKd3 on the first sub-mat region SMT(1) may be spaced apart from the blocks BLKr and BLKd1 to BLKd3 on the second sub-mat region SMT(2).

The blocks BLKr and BLKd1 to BLKd3 may include memory blocks BLKr and dummy blocks BLKd1 to BLKd3. Data storage/erase/read operations are actually performed in the memory blocks BLKr. The Data storage/erase/read operations are not performed in the dummy blocks BLKd1 to BLKd3. The dummy blocks BLKd1 to BLKd3 may include first to third dummy blocks BLKd1 to BLKd3 arranged side by side in the second direction D2. The first and third dummy blocks BLKd1 and BLKd3 may each have the same planar and cross-sectional structure as the memory blocks BLKr. The second dummy block BLKd2 may vertically overlap the mat separation region MSR. As used herein, “an element A vertically overlaps an element B” (or similar language) means that there is at least one line that extends in a vertical direction and intersects both the elements A and B.

End portions of the blocks BLKr, BLKd1 to BLKd3 may have a staircase shape (i.e., a stepped profile) adjacent to a center of the mat regions MT(or adjacent to between the first and second sub-mat regions SMT(1) and SMT(2)). The end portions of the blocks BLKr and BLKd1 to BLKd3 disposed on the first sub-mat region SMT(1) may have a staircase shape (i.e., a stepped profile) on the first decoder region DR(1). The end portions of the blocks BLKr and BLKd1 to BLKd3 disposed on the second sub-mat region SMT(2) may have a staircase shape (i.e., a stepped profile) on the second decoder region DR(2). For example, the memory blocks BLKr may include first memory blocks BLKr (1) on the first sub-mat region SMT(1) and second memory blocks BLKr (2) on the second sub-mat region SMT(2). The first memory blocks BLKr (1) are spaced apart from the second memory blocks BLKr (2). End portions of each of the first memory blocks BLKr (1) may overlap the first decoder region DR(1) and may form a staircase shape (i.e., a stepped profile) on the first decoder region DR(1). End portions of each of the second memory blocks BLKr (2) may overlap the second decoder region DR(2) and may form a staircase shape (i.e., a stepped profile) on the second decoder region DR(2).

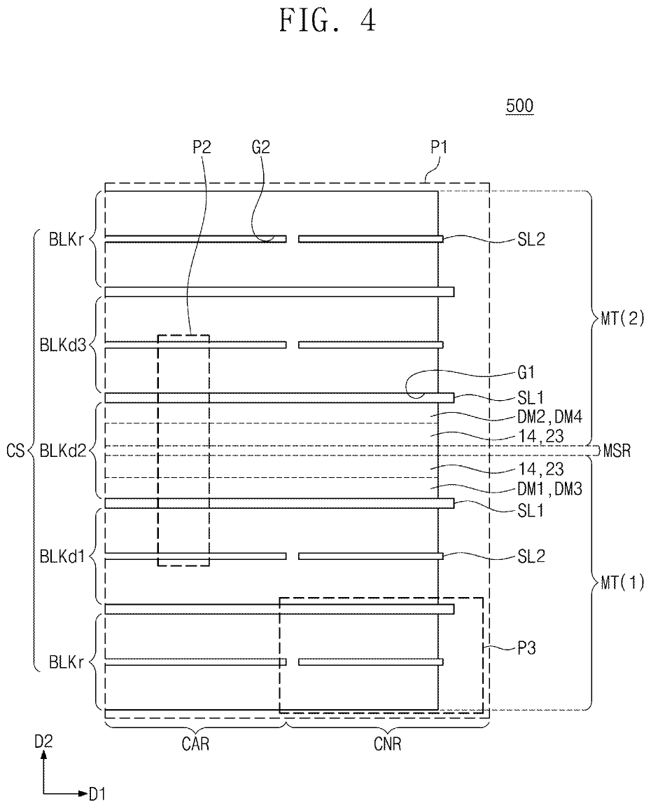

FIG. 4 is an enlarged view of portion ‘P1’ of FIG. 2B.

Referring to FIG. 4, the blocks BLKr and BLKd1 to BLKd3 may each include a cell region CAR and a connection region CNR. The connection region CNR may overlap the decoder region DR. Block separation patterns SL1 are interposed between the blocks BLKr and BLKd1 to BLKd3. The block separation patterns SL1 may have a continuous line shape without disconnection in the first direction D1. The block separation patterns SL1 may be disposed in a first groove G1. A space between the block separation patterns SL1 may be constant. Central separation patterns SL2 may be disposed at centers of the memory blocks BLKr and the first and third dummy blocks BLKd1 and BLKd3, respectively. The central separation pattern SL2 may be disposed within a second groove G2. The central separation pattern SL2 has a line shape extending from the cell region CAR in the first direction D1, but may be cut off in the connection region CNR to have a discontinuous section. The central separation pattern SL2 is not disposed in the second dummy block BLKd2. The block separation patterns SL1 and the central separation pattern SL2 may each have a single-layer or multi-layer structure of at least one of a silicon oxide layer, a silicon nitride layer, a silicon oxynitride layer, or a porous insulating layer.

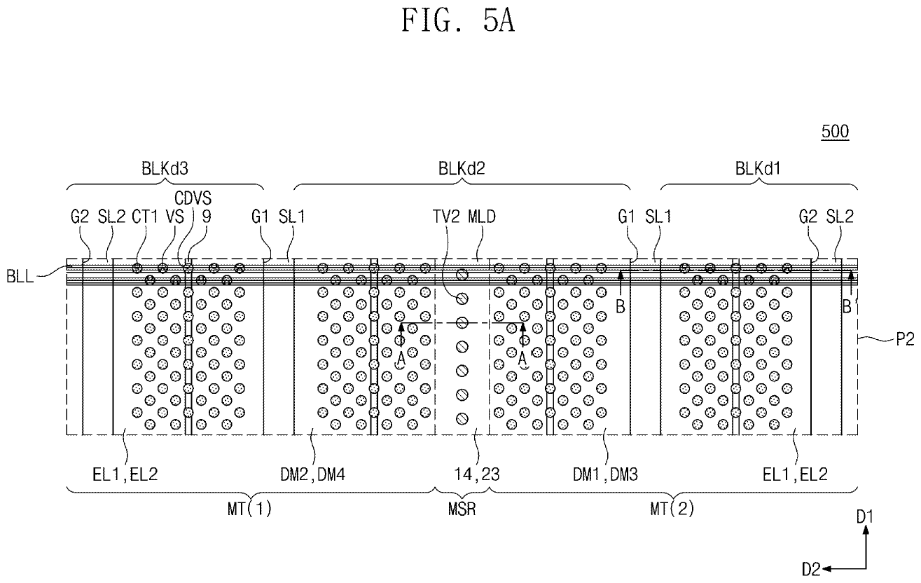

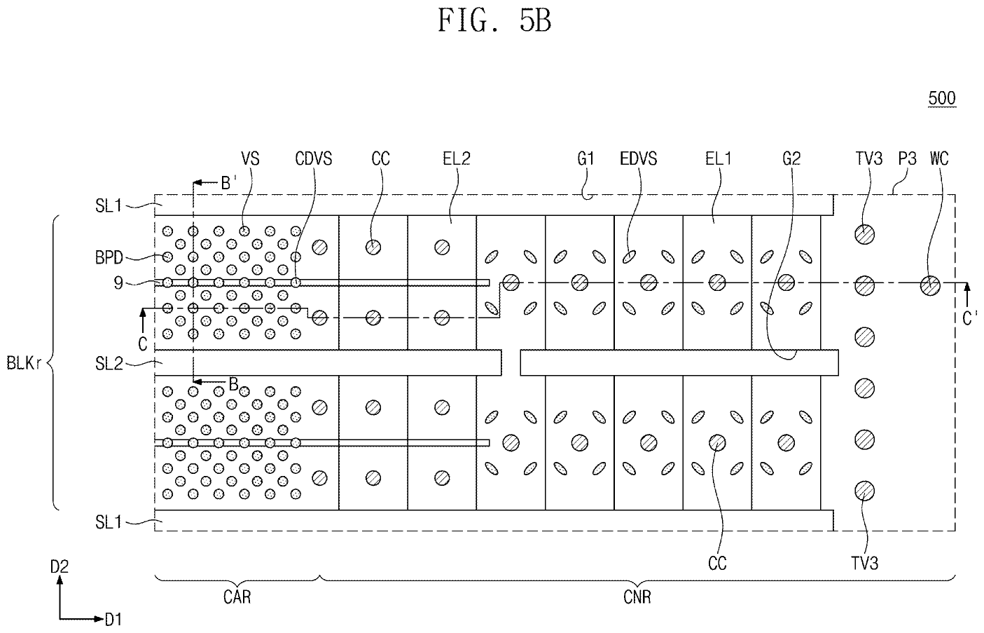

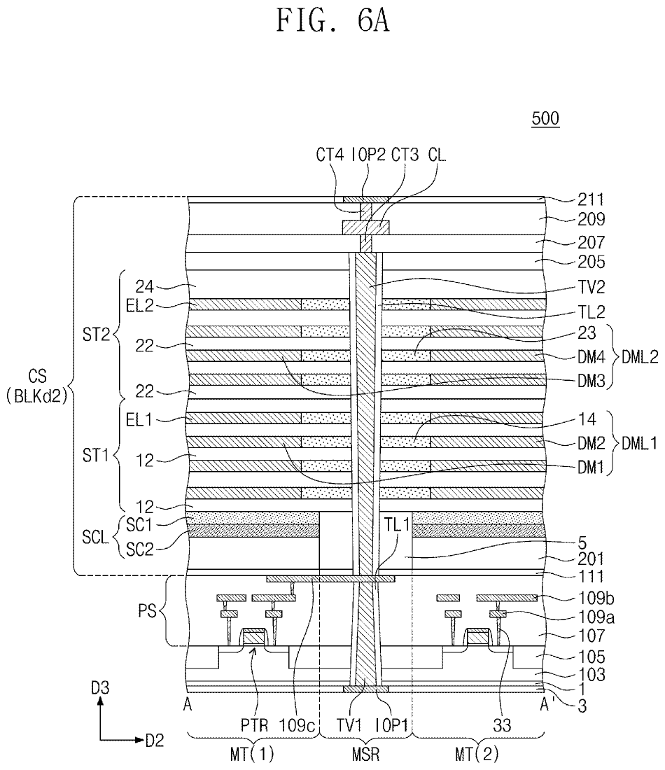

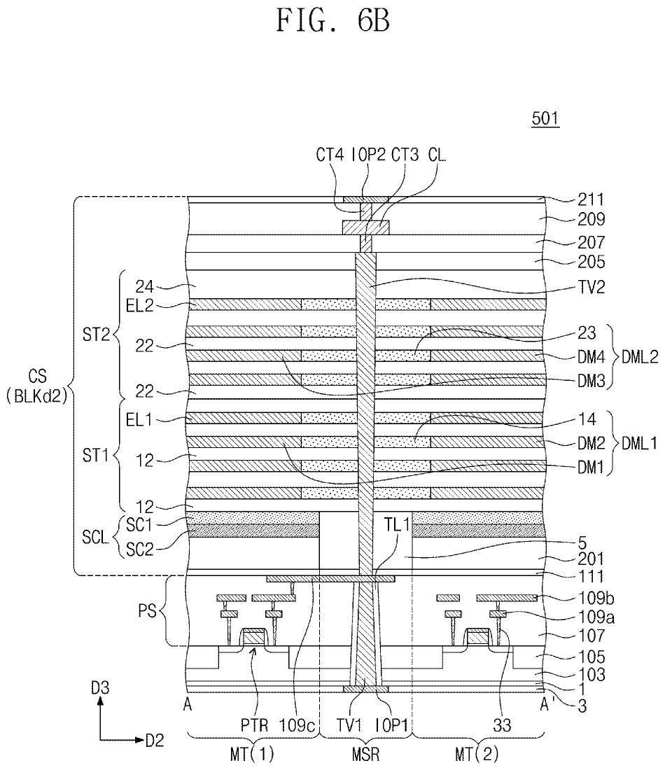

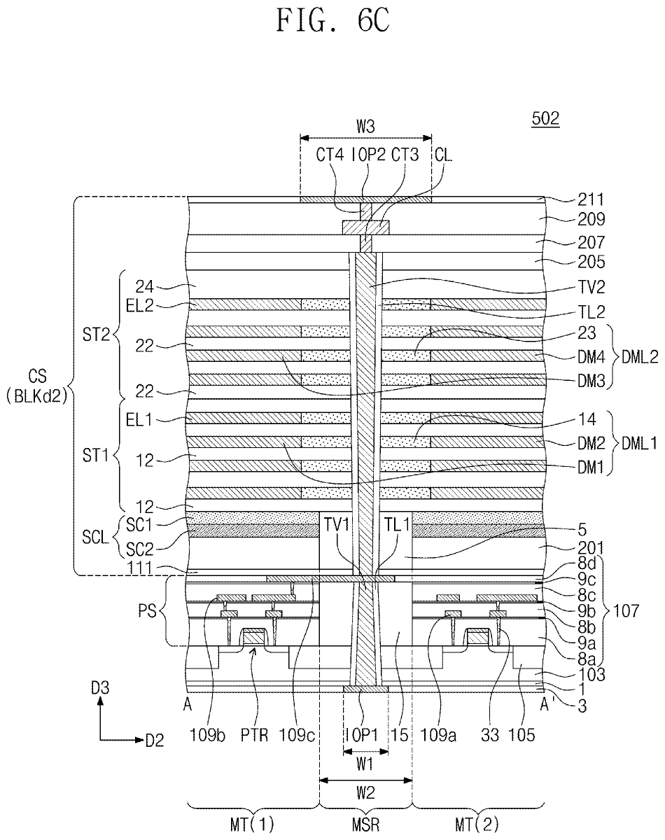

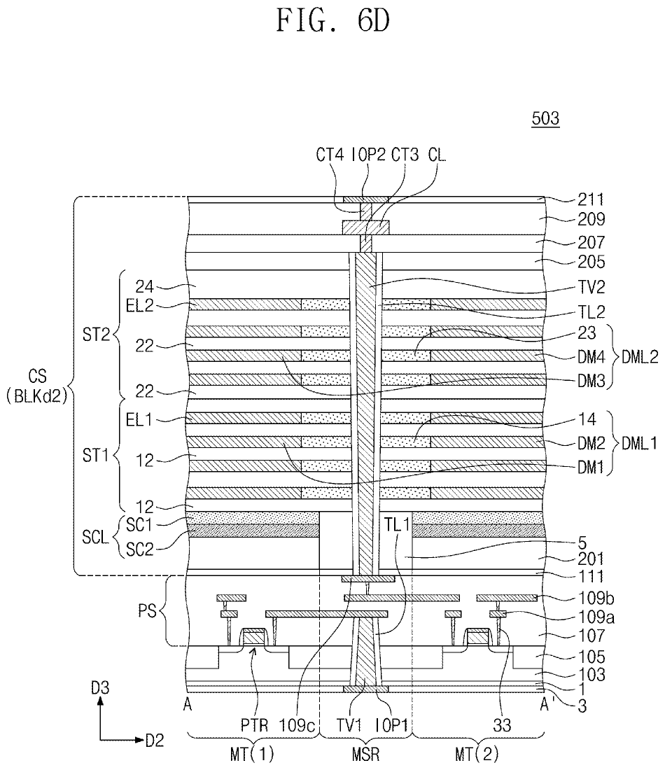

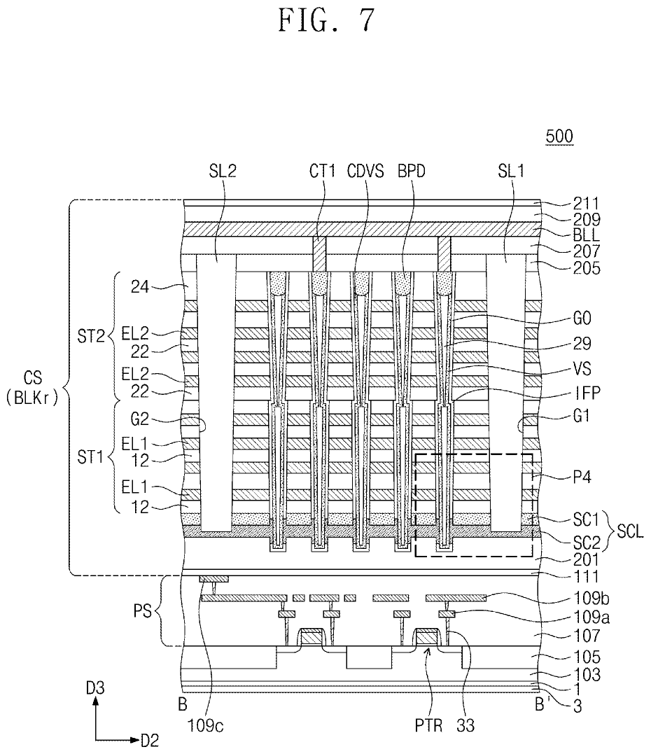

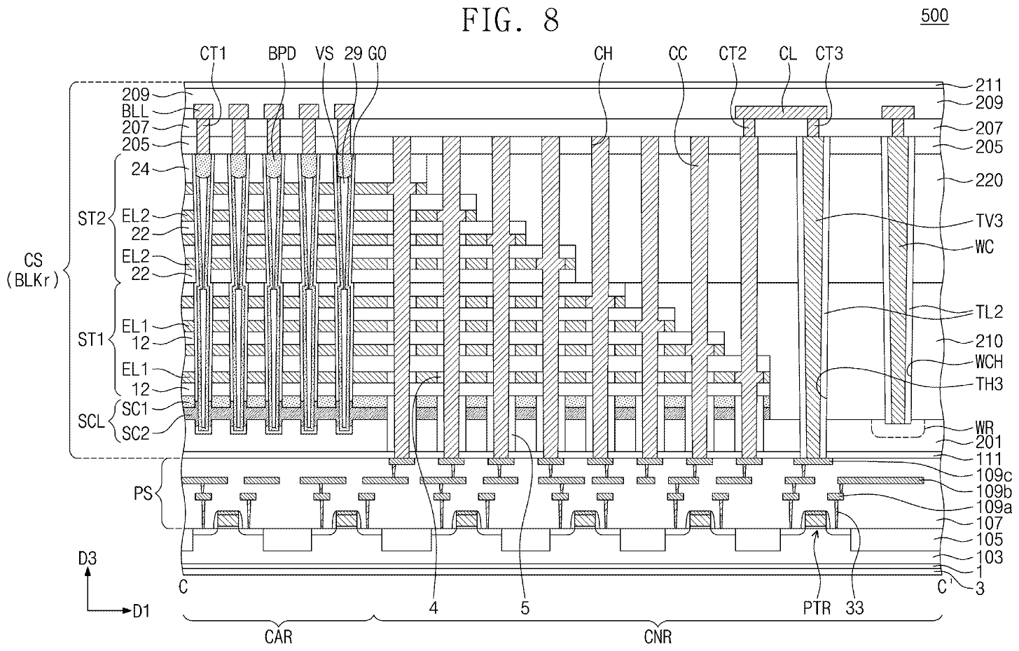

FIG. 5A is an enlarged view of portion ‘P2’ of FIG. 4. FIG. 5B is an enlarged view of portion ‘P3’ of FIG. 4. FIGS. 6A to 6D are cross-sectional views taken along line A-A′ of FIG. 5A according to some embodiments of the inventive concepts. FIG. 7 is a cross-sectional view taken along line B-B′ of FIG. 5B according to some embodiments of the inventive concepts. FIG. 8 is a cross-sectional view taken along line C-C′ of FIG. 5B according to some embodiments of the inventive concepts.

Referring to FIGS. 5A, 5B, 6A, 7, and 8, the substrate 103 may be a silicon single crystal substrate or a silicon on insulator (SOI) substrate. A lower surface of the substrate 103 may be covered with a first lower insulating layer 1 and a second lower insulating layer 3. The first lower insulating layer 1 may have a single-layer or multi-layer structure of at least one of, for example, silicon oxide or silicon nitride. The second lower insulating layer 3 may be formed of silicon carbonitride (SiCN).

A device isolation layer 105 may be disposed on the substrate 103 to define active regions. The peripheral circuit structure PS includes peripheral circuits. Peripheral transistors PTR may be disposed on the active regions. The peripheral transistors PTR may each include a peripheral gate electrode, a peripheral gate insulating layer, and peripheral source/drain regions disposed on both sides of the substrate 103 adjacent thereto. The peripheral transistors PTR may be covered with a peripheral interlayer insulating layer 107. The peripheral interlayer insulating layer 107 may have a single-layer or multi-layer structure of at least one of a silicon oxide layer, a silicon nitride layer, a silicon oxynitride layer, or a porous insulating layer. Peripheral interconnection lines 109a to 109c and peripheral contacts 33 may be disposed within the peripheral interlayer insulating layer 107. The peripheral interconnection lines 109a to 109c and the peripheral contacts 33 may include a conductive layer.

Some of the peripheral interconnection lines 109a to 109c and the peripheral contacts 33 may be electrically connected to the peripheral transistors PTR. The peripheral transistors PTR, the peripheral interconnection lines 109a to 109c, and the peripheral contacts 33 may constitute the page buffer circuit 1120 and the decoder circuit 1110 of FIG. 1A. The peripheral interconnection lines 109a to 109c may include first, second, and third peripheral interconnection lines 109a, 109b, and 109c.

An interface layer 111 is disposed on the peripheral circuit structure PS. The interface layer 111 may include a material that has etch selectivity with respect to a semiconductor layer 201 and the surrounding peripheral interlayer insulating layer 107. For example, the interface layer 111 may include silicon nitride or silicon oxide. The interface layer 111 may also be called an adhesive layer.

A cell array structure CS is disposed on the interface layer 111. Each of the blocks BLKr, BLKd1 to BLKd3 belonging to the cell array structure CS may include the semiconductor layer 201, a source structure SCL, a first stacked structure ST1, a second stacked structure ST2, and first to fourth upper insulating layers 205, 207, 209, and 211 that are alternately stacked. The first stacked structure ST1 may include first electrode layers EL1 and first inter-electrode insulating layers 12 that are alternately stacked. The second stacked structure ST2 may include alternately stacked second electrode layers EL2 and second inter-electrode insulating layers 22, and an uppermost second inter-electrode insulating layer 24 located on the uppermost layer thereof. The semiconductor layer 201 may be, for example, a silicon single crystal layer, a silicon epitaxial layer, or an SOI substrate. For example, the semiconductor layer 201 may be doped with an impurity of a first conductivity type. The impurity of the first conductivity type may be, for example, P-type boron. Alternatively, the first conductivity type impurity may be N-type arsenic or phosphorus.

Among the first electrode layers EL1, the one disposed at the lowermost level and the one disposed at the uppermost level may correspond to the gate lower lines LL1 and LL2 of FIG. 1A, which may be respectively used as gate electrodes of the lower erase control transistor LT1 and the ground selection transistor LT2 (e.g., see FIG. 1A).

At least two second electrode layers EL2 disposed at the uppermost level of the memory blocks BLKr and the first and third dummy blocks BLKd1 and BLKd3 respectively may be separated into a plurality of lines by a line separation pattern 9 and the second groove

G2 to form gate upper lines UL1 and UL2 (e.g., see FIG. 1A). Among the second electrode layers EL2, the uppermost one and the one which is disposed below may correspond to the gate electrodes of the upper transistors UT1 and UT2 (e.g., see FIG. 1A), that is, the upper erase control transistor UT2 and the string selection transistor UT1, respectively. Other electrode layers EL1 and EL2 may correspond to the word lines WL of FIG. 1A. At least one of the other electrode layers EL1 and EL2 may be a dummy word line that does not actually electrically operate.

The electrode layers EL1 and EL2 may include at least one selected from, for example, a doped semiconductor (e.g., doped silicon, etc.), a metal (e.g., tungsten, copper, aluminum, etc.), a conductive metal nitride (e.g., titanium nitride, tantalum nitride, etc.)) or a transition metal (e.g., titanium, tantalum, etc.). The inter-electrode insulating layers 12, 22, and 24 may include at least one single layer or multilayer selected from a silicon oxide layer, a silicon nitride layer, a silicon oxynitride layer, or a porous insulating layer.

The source structure SCL may include a first source pattern SC1 interposed between the inter-electrode insulating layer 12 located at the lowest layer and the semiconductor layer 201, and a second source pattern SC2 interposed between the first source pattern SC1 and the semiconductor layer 201. Although not illustrated, a portion of the first source pattern SC1 may penetrate (i.e., extend into) the second source pattern SC2 and may be in contact with the semiconductor layer 201. The first source pattern SC1 may include a semiconductor pattern doped with impurities, for example, polysilicon doped with impurities of a first conductivity type. The second source pattern SC2 may include a semiconductor pattern doped with impurities, for example, polysilicon doped with impurities. The second source pattern SC2 may further include a semiconductor material different from the first source pattern SC1. The conductivity type of the impurity doped into the second source pattern SC2 may be the same as the conductivity type of the impurity doped into the first source pattern

SC1. A concentration of impurities doped in the second source pattern SC2 may be the same as or different from a concentration of impurities doped in the first source pattern SC1. The source structure SCL may correspond to the common source line CSL of FIG. 1A.

In the memory blocks BLKr and the first and third dummy blocks BLKd1 and BLKd3, the inter-electrode insulating layers 12, 22, and 24 and the electrode layers EL1 and EL2 may be penetrated (i.e., extended into) by cell vertical patterns VS and central dummy vertical patterns CDVS, respectively. Cell vertical patterns VS and central dummy vertical patterns CDVS may be disposed on the cell region CAR. The central dummy vertical patterns CDVS may be arranged in one row in the first direction D1. The line separation pattern 9 may be disposed between upper portions of the central dummy vertical patterns CDVS. A gate insulating layer GO may be interposed between the electrode layers EL1 and EL2 and the cell vertical patterns VS and between the electrode layers EL1 and EL2 and the central dummy vertical patterns CDVS. The cell vertical patterns VS and the central dummy vertical patterns CDVS may each have a hollow cup shape. The cell vertical patterns VS and the central dummy vertical patterns CDVS may include, for example, a silicon single crystal layer or polysilicon that is not doped with impurities. Sidewalls of the cell vertical patterns VS and the central dummy vertical patterns CDVS may have an inflection point IFP adjacent to an interface between the first stacked structure ST1 and the second stacked structure ST2 (e.g., see FIG. 7).

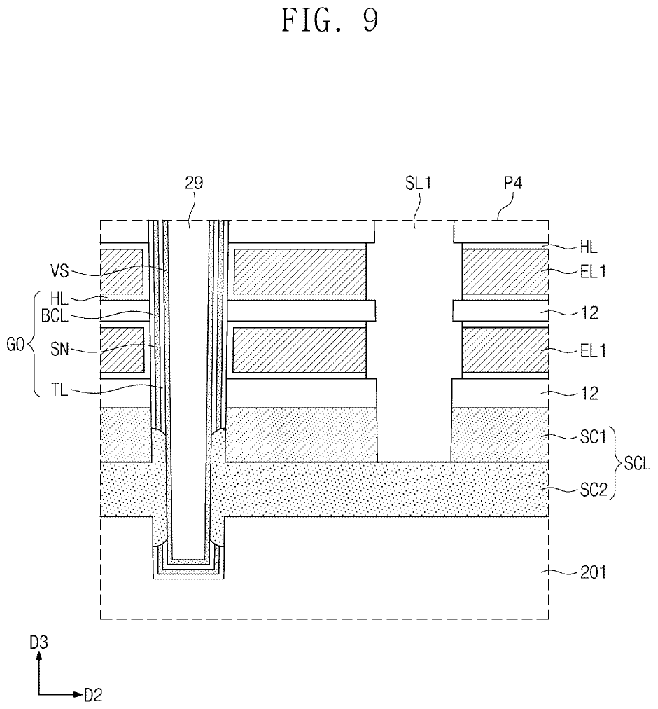

An interior of the cell vertical patterns VS and the central dummy vertical patterns CDVS may be filled with a buried insulating pattern 29. For example, the buried insulating pattern 29 may have a single-layer or multi-layer structure of at least one of a silicon oxide layer, a silicon nitride layer, or a silicon oxynitride layer. A bit line pad BPD may be disposed on the cell vertical patterns VS and the central dummy vertical patterns CDVS, respectively. The bit line pad BPD may include polysilicon doped with impurities, or metal such as tungsten, aluminum, or copper. The second source pattern SC2 may penetrate (i.e., extend into) the gate insulating layer GO and may be in contact with lower sidewalls of the cell vertical patterns VS and the central dummy vertical patterns CDVS, respectively. FIG. 9 is an enlarged view of portion ‘P4’ of FIG. 7.

Referring to FIGS. 7 and 9, the gate insulating layer GO may include a tunnel insulating layer TL, a charge storage layer SN, and a blocking insulating layer BCL. The charge storage layer SN may be a trap insulating layer, a floating gate electrode, or an insulating layer including conductive nano dots. In detail, the charge storage layer SN may include at least one of a silicon nitride layer, a silicon oxynitride layer, a silicon-rich nitride layer, nanocrystalline silicon, or a laminated trap layer. The tunnel insulating layer TL may be one of materials having a larger band gap than the charge storage layer SN, and the blocking insulating layer BCL may be a high dielectric layer such as an aluminum oxide layer or a hafnium oxide layer. The gate insulating layer GO may further include a high dielectric layer HL. The high dielectric layer HL may be interposed between the blocking insulating layer BCL and the electrode layers EL1 and EL2. The high dielectric layer HL may also be interposed between the electrode layers EL1 and EL2 and the inter-electrode insulating layers 12, 22, and 24. The high dielectric layer HL may be a layer having a higher dielectric constant than a silicon oxide layer and may include, for example, a metal oxide layer such as a hafnium oxide layer or an aluminum oxide layer. The second source pattern SC2 may penetrate (i.e., extend into) the gate insulating layer GO and may be in contact with the cell vertical patterns VS. A lower portion of the gate insulating layer GO may be separated from an upper portion of the gate insulating layer GO by the second source pattern SC2. A portion of the block separation pattern SL1 may protrude toward the electrode layers EL1 and EL2 in the second direction D2 and may be interposed between adjacent inter-electrode insulating layers 12, 22, and 24. A sidewall of the block separation pattern SL1 may have an uneven structure. Side walls of the central separation pattern SL2 may also be the same as or similar to the block separation pattern SL1.

Referring to FIG. 7, the block separation pattern SL1 and the central separation pattern SL2 may penetrate (i.e., extend into) the first upper insulating layer 205 and the stacked structures ST1 and ST2, respectively. Although not illustrated, a conductive line or a conductive contact plug may be disposed in the block separation pattern SL1 and the central separation pattern SL2 to be in contact with the source structure SCL.

Referring to FIG. 6A, the peripheral circuit structure PS may be penetrated (i.e., extended into) in the mat separation region MSR by the first through-via TV1. The first through-via TV1 may penetrate (i.e., extend into) the device isolation layer 105, the substrate 103, and the first lower insulating layer 1. The first through-via TV1 may have a narrower width as the first through-via TV1 goes upward. That is, a width of the first through-via TV1 may decrease as it extends toward the cell array structure CS in a third direction D3. For example, the third direction D3 may intersect the first and second directions D1 and D2 and may be perpendicular to an upper surface of the substrate 103. A first input/output pad IOP1 is disposed within a second lower insulating layer 3.

A lower portion of the first through-via TV1 is in contact with the first input/output pad IOP1. An upper portion of the first through-via TV1 may be in contact with one of the third peripheral interconnection lines 109c, as illustrated in FIGS. 6A to 6C. Alternatively, the upper portion of the first through-via TV1 may be in contact with one of the first peripheral interconnection lines 109a, like the semiconductor memory device 503 of FIG. 6D. A side surface of the first through-via TV1 may be surrounded by a first via

insulating layer TL1. The first through-via TV1 may be formed of a conductive material and may include, for example, a metal such as tungsten, copper, aluminum, or titanium. The first input/output pad IOP1 may be formed of, for example, copper. The first input/output pad IOP1 may have a first width W1 (e.g., see FIG. 6C).

Referring to FIG. 6C, in one example, the peripheral interlayer insulating layer 107 may include a first peripheral interlayer insulating layer 8a, a first peripheral etch stop layer 9a, a second peripheral interlayer insulating layer 8b, a second peripheral etch stop layer 9b, a third peripheral interlayer insulating layer 8c, a third peripheral etch stop layer 9c, and a fourth peripheral interlayer insulating layer 8d. A mat separation insulating pattern 15 (also referred to as a mat separation insulating layer 15) may penetrate (i.e., extend into) the first peripheral interlayer insulating layer 8a, the first peripheral etch stop layer 9a, the second peripheral interlayer insulating layer 8b, the second peripheral etch stop layer 9b, the third peripheral interlayer insulating layer 8c, and the third peripheral etch stop layer 9c.

Accordingly, sidewalls of the first peripheral interlayer insulating layer 8a, the first peripheral etch stop layer 9a, the second peripheral interlayer insulating layer 8b, the second peripheral etch stop layer 9b, the third peripheral interlayer insulating layer 8c, and the third peripheral etch stop layer 9c may be aligned with each other. The mat separation insulating pattern 15 may have a second width W2. The second width W2 may be different from the first width W1. For example, the second width W2 may be larger than the first width W1. For example, the second width W2 and the first width W1 may be taken in the second direction D2.

Referring to FIGS. 6A and 8, lower insulating patterns 5 on the mat separation region MSR and connection region CNR may penetrate (i.e., extend into) the source structure SCL and the semiconductor layer 201 to be in contact with the interface layer 111. The lower insulating patterns 5 may be formed of, for example, silicon oxide.

Referring to FIGS. 5A and 6A, the second dummy block BLKd2 may include inter-electrode insulating layers 12, 22, and 24 that are sequentially stacked, and dummy electrode layers DML1 and DML2 interposed between the inter-electrode insulating layers 12, 22, and 24, respectively. The dummy electrode layers DML1 and DML2 may include first dummy electrode layers DML1 included in the first stacked structure ST1 and second dummy electrode layers DML2 included in the second stacked structure ST2. The first dummy electrode layers DML1 may include a first dummy electrode DM1, a second dummy electrode DM2, respectively, and a first mold insulating layer 14 interposed therebetween. The second dummy electrode layers DML2 may include a third dummy electrode DM3, a fourth dummy electrode DM4, and a second mold insulating layer 23 interposed therebetween. The first dummy electrode DM1 and the second dummy electrode DM2 may be a portion of the first electrode layer EL1. The third dummy electrode DM3 and the fourth dummy electrode DM4 may be a portion of the second electrode layer EL2. The first mold insulating layer 14 and the second mold insulating layer 23 may be formed of the same material. The first mold insulating layer 14 and the second mold insulating layer 23 may be formed of a material that has etch selectivity with respect to the inter-electrode insulating layers 12, 22, and 24, for example, silicon nitride. Horizontal widths of the first to fourth dummy electrodes DM1 to DM4 may be the same.

On the mat separation region MSR, the second through-via TV2 may penetrate (i.e., extend into) the second stacked structure ST2, the first stacked structure ST1, the lower insulating pattern 5, and the interface layer 111 to be in contact with third peripheral interconnection lines 109c. The second through-via TV2 may have a width that narrows downward. That is, a width of the second through-via TV2 may decrease as it extends toward the peripheral circuit structure PS in the third direction D3. The second through-via TV2 may penetrate (i.e., extend into) the inter-electrode insulating layers 12, 22, and 24, the first mold insulating layer 14, and the second mold insulating layer 23. As illustrated in FIG. 6A, a sidewall of the second through-via TV2 may be surrounded by a second via insulating layer TL2. Alternatively, like the semiconductor memory device 501 of FIG. 6B, the sidewall of the second through-via TV2 may not be surrounded by the second via insulating layer TL2, and may be in direct contact with the first mold insulating layer 14 and the second mold insulating layer 23.

The second through-via TV2 may be formed of a conductive material and may include, for example, a metal such as tungsten, copper, aluminum, or titanium. The second through-via TV2 may vertically overlap the first through-via TV1.

Referring to FIGS. 5A, 5B, 6A, 7, and 8, a second upper insulating layer 207 may be disposed on the first upper insulating layer 205. First conductive lines BLL extending in the second direction D2 and parallel to each other may be disposed on the second upper insulating layer 207. The first conductive lines BLL may correspond to the bit lines BL in FIG. 1A. In the cell region CAR, first contacts CT1 may penetrate (i.e., extend into) the first and second upper insulating layers 205 and 207 to connect the bit line pads BPD disposed on the cell vertical patterns VS to one of the first conductive lines BLL. The first contacts CT1 may not be disposed on the bit line pad BPD disposed on the central dummy vertical pattern CDVS. As used herein, “an element A connected to an element B” (or similar language) means that the element A is physically and/or electrically connected to the element B.

Third contacts CT3 may penetrate (i.e., extend into) the second upper insulating layer 207. One of the third contacts CT3 may be in contact with the second through-via TV2. The stacked structures ST1 and ST2 belonging to the blocks BLKr, BLKd1 to BLKd3, respectively, may have a staircase shape (i.e., a stepped profile) in the connection region CNR. That is, the electrode layers EL1 and EL2 and the inter-electrode insulating layers 12, 22, and 24 may have a staircase shape (i.e., a stepped profile) in the connection region CNR. As the electrode layers EL1 and EL2 and the inter-electrode insulating layers 12, 22, and 24 become closer to the peripheral circuit structure PS, the electrode layers EL1 and EL2 and the inter-electrode insulating layers 12, 22, and 24 may be elongated in the first direction D1 to protrude. Ends of the first stacked structures ST1 in the connection region CNR may be covered with a first flat insulating layer 210. Ends of the second stacked structures ST2 in the connection region CNR may be covered with a second flat insulating layer 220. The flat insulating layers 210 and 220 may include a silicon oxide layer or a porous insulating layer.

Ends of the electrode layers EL1 and EL2 may be connected to cell contact plugs CC, respectively (e.g., see FIG. 8). The cell contact plugs CC may penetrate (i.e., extend into) the first upper insulating layer 205 and the inter-electrode insulating layers 12, 22, and 24 and may be in contact with corresponding ones of the electrode layers EL1 and EL2, respectively.

One of the cell contact plugs CC may be in contact with one of the electrode layers EL1 and EL2, a side surface of the one cell contact plug CC may protrude sideways at a level of the one electrode layer EL1 or EL2. For example, a side surface of the one cell contact plug CC may protrude in the first direction D1 to contact one of the electrode layers EL1 and EL2. A contact insulating layer 4 may be interposed between the one cell contact plug CC and other electrode layers EL1 and EL2 that are not connected to the one cell contact plug CC. A second contact CT2 may be connected to the cell contact plugs CC. Connection lines CL may be disposed on the second upper insulating layer 207.

Referring to FIG. 5B, edge dummy vertical patterns EDVS may penetrate (i.e., extend into) ends of the flat insulating layers 210 and 220, the step-shaped electrode layers EL1 and EL2, and the inter-electrode insulating layers 12, 22, and 24. The edge dummy vertical patterns EDVS may have an oval shape that is elongated in a certain direction when viewed in a plan view. A cross-section of the edge dummy vertical patterns EDVS may be the same as or similar to the cell vertical pattern VS or the central dummy vertical pattern CDVS of FIG. 7. Interiors of the edge dummy vertical patterns EDVS may also be filled with buried insulating patterns 29. A gate insulating layer GO may be interposed between the edge dummy vertical patterns EDVS and the electrode layers EL1 and EL2.

Referring to FIGS. 5B and 8, in the connection region CNR, a third through-via TV3 may penetrate (i.e., extend into) the first upper insulating layer 205, the flat insulating layers 210 and 220, the semiconductor layer 201, and the interface layer 111 to be in contact with one of the third peripheral interconnection lines 109c. In the present example, the third through-via TV3 may be spaced apart from the stacked structures ST1 and ST2. The third through-via TV3 may be connected to the connection line CL through a second contact CT2 and a third contact CT3 disposed in the second upper insulating layer 207, respectively. Accordingly, the electrode layers EL1 and EL2 may be connected to, for example, a decoder circuit (e.g., the decoder circuit 1110 in FIG. 1A) of the peripheral circuit structure PS. A sidewall of the third through-via TV3 may be surrounded by a second via insulating layer TL2.

The third through-vias TV3 and the second through-vias TV2 may each include at least one metal selected from tungsten, aluminum, copper, titanium, or tantalum. The first and second via insulating layers TL1 and TL2 may each include an insulating material such as a silicon oxide layer, a silicon nitride layer, and/or a silicon oxynitride layer. The cell contact plugs CC, the third through-vias TV3, and the second through-vias TV2 may have the same height. For example, respective upper surfaces of the cell contact plugs CC, the third through-vias TV3, and the second through-vias TV2 may be coplanar.

Referring to FIG. 8, a ground region WR may be disposed in the semiconductor layer 201 at a location spaced apart from the third through-vias TV3. The ground region WR may be doped with an impurity of the first conductivity type that is doped in the semiconductor layer 201 and may be doped at a higher concentration than the concentration of the impurity doped in the semiconductor layer 201. In the connection region CNR, a ground contact plug WC may penetrate (i.e., extend into) the first upper insulating layer 205 and the flat insulating layers 210 and 220 and may be in contact with the ground region WR.

As illustrated in FIG. 6A, the connection lines CL may be covered with a third upper insulating layer 209. A fourth contact CT4 may penetrate (i.e., extend into) the third upper insulating layer 209. A fourth upper insulating layer 211 is disposed on the third upper insulating layer 209. A second input/output pad IOP2 is disposed within the fourth upper insulating layer 211. For example, the second input/output pad IOP2 may be on an upper portion of the cell array structure CS. The second input/output pad IOP2 may be in contact with the fourth contact CT4. The third upper insulating layer 209 may have a single-layer or multi-layer structure of at least one of silicon oxide or silicon nitride. The fourth upper insulating layer 211 may be formed of, for example, SiCN. The second input/output pad IOP2 may be formed of, for example, copper. The first input/output pad IOP1, the second input/output pad IOP2, the first through-via TV1, and the second through-via TV2 may vertically overlap each other and may be disposed on the mat separation region MSR.

Like the semiconductor memory device 502 of FIG. 6C, the second input/output pad IOP2 may have a third width W3. The third width W3 of the second input/output pad IOP2 may be equal to the first width W1 of the first input/output pad IOP1 as illustrated in FIG. 6A. Alternatively, the third width W3 of the second input/output pad IOP2 may be different from the first width W1 of the first input/output pad IOP1 as illustrated in FIG. 6C, and for example, may be larger than the first width W1 of the first input/output pad IOP1.

Accordingly, as the third width W3 is different from the first width W1, misalignment margin may be improved when a plurality of semiconductor memory devices 500 are stacked to form a semiconductor package. For example, the third width W3 may be taken in the second direction D2.

In the semiconductor memory device 500 according to the inventive concepts, first and second through-vias TV1 and TV2 and first and second input/output pads IOP1 and IOP2 are disposed on the mat separation region MSR. As a result, separate spaces for the first and second through-vias TV1 and TV2 and the first and second input/output pads IOP1 and IOP2 may be not required, thereby reducing the overall horizontal size of the semiconductor memory device.

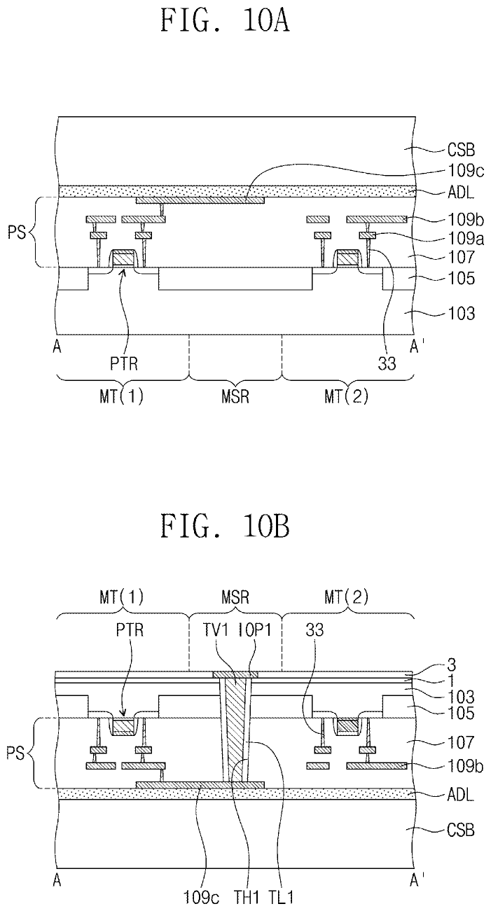

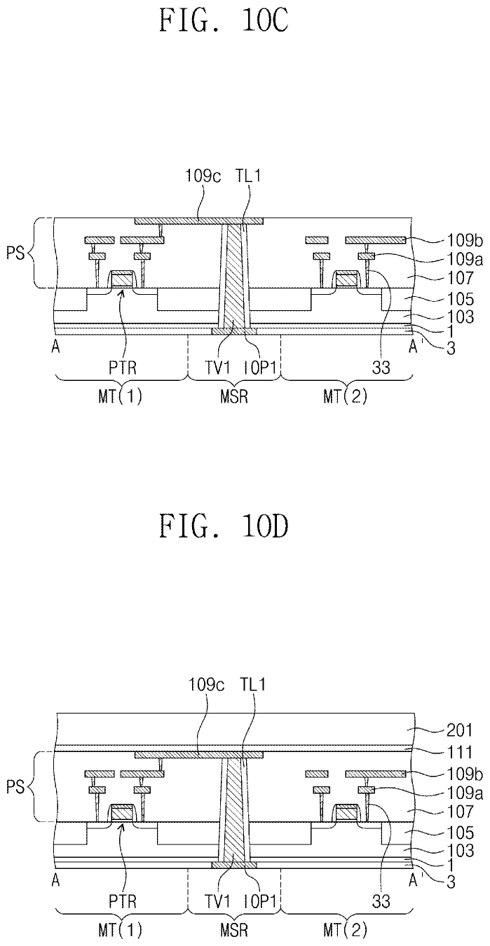

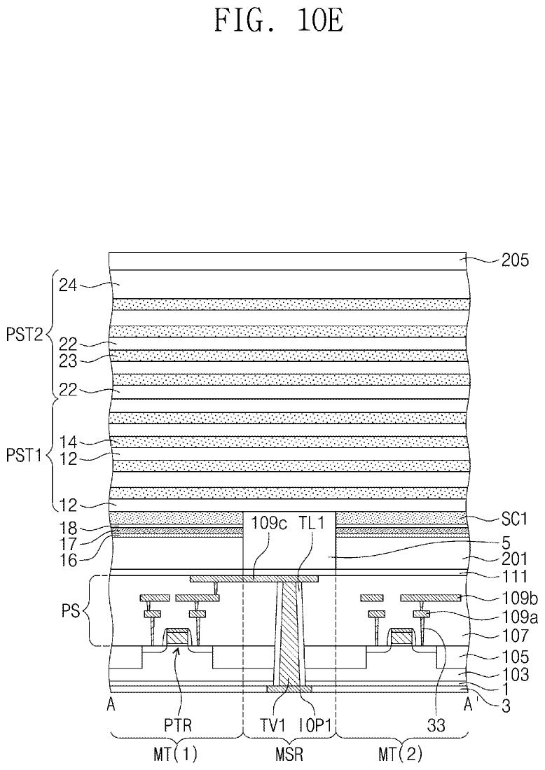

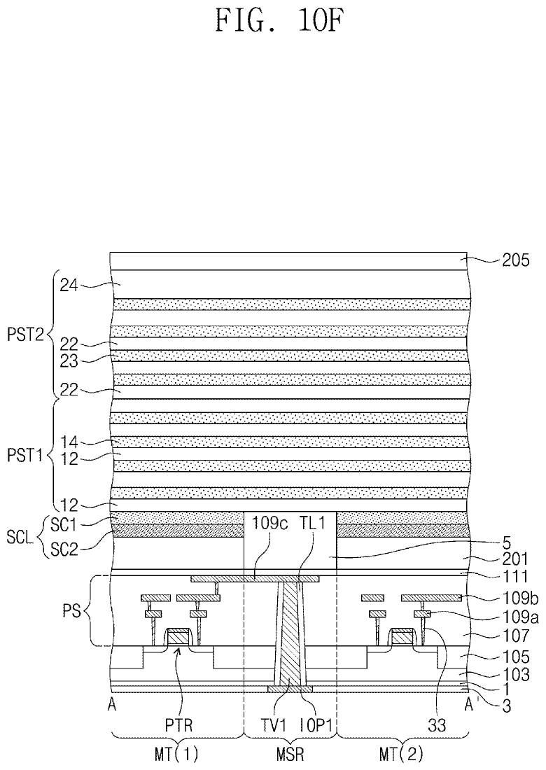

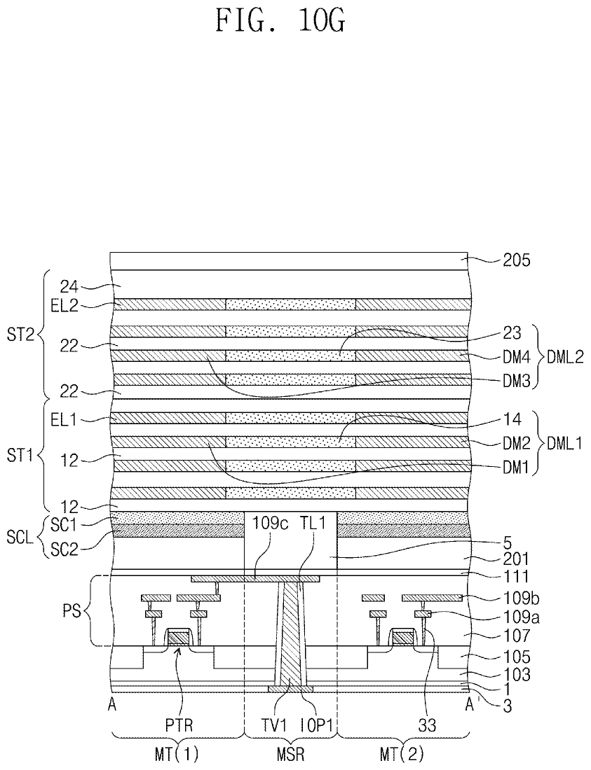

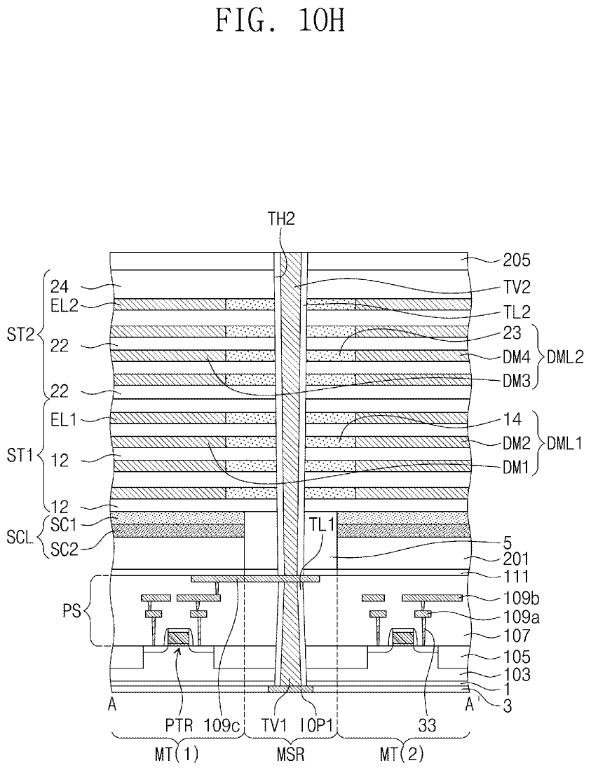

FIGS. 10A to 10H are cross-sectional views sequentially illustrating a process of manufacturing the semiconductor memory device of FIG. 6A.

Referring to FIG. 10A, a substrate 103 is provided. The substrate 103 includes mat regions MT and their mat separation region MSR, as explained with reference to FIGS. 2A, 2B, and 3. A device isolation layer 105 is formed on the substrate 103 to define active regions. Transistors PTR may be formed in the active regions. A multi-layer peripheral interlayer insulating layer 107 is formed to cover the transistors PTR, and peripheral contacts 33 and peripheral interconnection lines 109a to 109c are formed in the peripheral interlayer insulating layer 107. A carrier substrate CSB is bonded to the peripheral circuit structure PS via an adhesive layer ADL.

Referring to FIG. 10B, the structure of FIG. 10A may be turned over such that the substrate 103 is facing upward. A grinding process is performed to make a thickness of the substrate 103 a certain thickness. A first lower insulating layer 1 is formed on the substrate 103. In the mat separation region MSR, the first lower insulating layer 1, the substrate 103, the device isolation layer 105, and the peripheral interlayer insulating layer 107 are partially etched to form a first through-via hole TH1. A first via insulating layer TL1 is formed to cover an inner wall of the first through-via hole TH1. Then, the first through-via hole TH1 is filled with a conductive layer and is processed with an anisotropic etching or grinding process to form the first through-via TV1. A second lower insulating layer 3 is formed on the first lower insulating layer 1. The second lower insulating layer 3 is etched to form a trench exposing the first through-via TV1 and the trench is filled with a conductive layer to form a first input/output pad IOP1.

Referring to FIG. 10C, the adhesive layer ADL and the carrier substrate CSB are separated from the peripheral circuit structure PS to expose an upper surface of the peripheral circuit structure PS.

Referring to FIG. 10D, an interface layer 111 is sequentially formed on the peripheral circuit structure PS. A semiconductor layer 201 is formed on the interface layer 111. A semiconductor epitaxial layer may be formed or a semiconductor single crystal substrate may be attached to the interface layer 111, thereby forming the semiconductor layer 201. The semiconductor layer 201 may be doped with, for example, a first conductivity type impurity.

A ground region WR may be formed in the semiconductor layer 201 as illustrated in FIG. 8. The ground region WR may be formed by doping impurities of the first conductivity type, and may have a higher concentration than a concentration of impurities doped in the semiconductor layer 201. The semiconductor layer 201 may include a cell region CAR and a connection region CNR as illustrated in FIGS. 4, 5B, and 8.

Referring to FIG. 10E, a first buffer layer 16, a first sacrificial layer 17, a second buffer layer 18, and a first source pattern SC1 are sequentially stacked on the semiconductor layer 201. Although not illustrated, a portion of the first source pattern SC1 may be formed to be in contact with an upper surface of the semiconductor layer 201. To this end, a portion of the first source pattern SC1 may penetrate (i.e., extend into) the second buffer layer 18, the first sacrificial layer 17, and the first buffer layer 16. A lower insulating pattern 5 penetrating (i.e., extending into) the first source pattern SC1, the second buffer layer 18, the first sacrificial layer 17, and the first buffer layer 16 on the mat separation region MSR and the connection region CNR is formed.

The first inter-electrode insulating layers 12 and the first mold insulating layers 14 are alternately stacked on the first source pattern SC1 to form a first preliminary stacked structure PST1. The first source pattern SC1 may be a polysilicon layer doped with impurities. The first and second buffer layers 16 and 18 and the inter-electrode insulating layers 12 may preferably include a silicon oxide layer. The first sacrificial layer 17 may include a material having an etch selectivity simultaneously with the first and second buffer layers 16 and 18, the first inter-electrode insulating layers 12, the first source pattern SC1, and the first mold insulating layers 14. For example, the first mold insulating layers 14 may be formed of a silicon nitride layer. The first sacrificial layer 17 may be a silicon germanium layer or a silicon oxynitride layer. Alternatively, the first sacrificial layer 17 may be a polysilicon layer doped with an impurity concentration that is different from the concentration of the impurity doped in the first source pattern SC1.

By repeatedly performing a trimming process and an anisotropic etching process, end portions of the first inter-electrode insulating layers 12 and the first mold insulating layers 14 in the connection region CNR may be formed into a staircase shape (i.e., a stepped profile).

At this time, the first buffer layer 16, the first sacrificial layer 17, the second buffer layer 18, and the first source pattern SC1 may also be partially etched to expose the upper surface of the semiconductor layer 201. A first flat insulating layer 210 is formed and a chemical mechanical polishing (CMP) process is performed to cover ends of the first preliminary stacked structure PST1.

In the cell region CAR, the first preliminary stacked structure PST1, the first source pattern SC1, the second buffer layer 18, the first sacrificial layer 17, the first buffer layer 16, and the semiconductor layer 201 are partially etched to form lower holes, and the lower holes are filled with a sacrificial material to form first sacrificial patterns. The first sacrificial patterns may be formed to define the positions of cell vertical patterns VS illustrated in FIGS. 5A and 5B.

The second inter-electrode insulating layers 22 and 24 and the second mold insulating layers 23 are alternately and repeatedly stacked on the first preliminary stacked structure PST1 and the first flat insulating layer 210 to form a second preliminary stacked structure PST2. The second inter-electrode insulating layers 22 and 24 may include the same material as the first inter-electrode insulating layers 12. The second mold insulating layers 23 may include the same material as the first mold insulating layers 14. By repeatedly performing the trimming process and the anisotropic etching process, end portions of the second inter-electrode insulating layers 22 and 24 and the second mold insulating layers 23 in the connection region CNR may be formed into a staircase shape (i.e., a stepped profile). A second flat insulating layer 220 is formed and a chemical mechanical polishing (CMP) process is performed to cover the ends of the second preliminary stacked structure PST2. Additionally, the second preliminary stacked structure PST2 may be etched in the cell region CAR to form upper holes exposing the first sacrificial patterns, respectively.

The first sacrificial patterns may be removed through the upper holes to expose lower holes. The upper holes and the lower holes that overlap each other may constitute vertical holes. As illustrated in FIG. 7, a gate insulating layer GO, a cell vertical pattern VS, a buried insulating pattern 29, and bit line pads BPD may be formed in the vertical holes, respectively.

Referring to FIGS. 7 and 10E, a first upper insulating layer 205 is formed on the second preliminary stacked structure PST2. The first upper insulating layer 205, the second preliminary stacked structure PST2, the first preliminary stacked structure PST1, the first source pattern SC1, and the second buffer layer 18 are sequentially etched. First grooves G1 and second grooves G2 exposing the first sacrificial layer 17 are formed. As illustrated in FIG. 4, the second groove G2 is not formed in the second dummy block BLKd2.

The second buffer layer 18, the first sacrificial layer 17, and the first buffer layer 16 may be removed through the first and second grooves G1 and G2 to form a first empty space. Here, a portion of the gate insulating layer GO may be removed to expose sidewalls of the cell vertical pattern VS and the central dummy vertical pattern CDVS. A second source layer may be conformally deposited to fill the first empty space through the first and second grooves G1 and G2, an anisotropic etching process may be performed to remove the second source layer in the first and second grooves G1 and G2, and the second source layer may be left in the first empty space to form a second source pattern SC2. Accordingly, the first source pattern SC1 and the second source pattern SC2 may form a source structure SCL.

Referring to FIGS. 7 and 10F, the first mold insulating layers 14 and the second mold insulating layers 23 may be removed by supplying an etchant through the first and second grooves G1 and G2 to form second empty spaces between the inter-electrode insulating layers 12, 22, and 24. A first conductive layer is conformally deposited to fill the second empty spaces through the first and second grooves G1 and G2. Then, an anisotropic etching process may be performed to remove the first conductive layer in the first and second grooves G1 and G2 to form electrode layers EL1 and EL2 in the second empty spaces. As a result, the first stacked structure ST1 and the second stacked structure ST2 may be formed. Before depositing the first conductive layer, the high dielectric layer HL illustrated in FIG. 9 may be conformally formed. As illustrated in FIG. 4, as the second dummy block BLKd2 does not have a second groove G2 and the etchant is supplied only through the first groove G1, the first mold insulating layers 14 and the second mold insulating layers 23 cannot be removed due to limitation in an etchant penetration length and some of the first mold insulating layers 14 and the second mold insulating layers 23 remain on the mat separation region MSR as illustrated in FIG. 10F.

Referring to FIGS. 7 and 10G, an insulating layer is conformally deposited and anisotropically etched to form a block separation pattern SL1 and a central separation pattern SL2 that fill the first and second grooves G1 and G2, respectively.

Referring to FIGS. 8 and 10H, in the connection region CNR, a cell contact hole CH for a cell contact plug CC, a third through-via hole TH3 for a third through-via TV3, and a ground contact hole WCH for a ground contact plug WC are formed. In addition, a second through-via hole TH2 is formed on the mat separation region MSR to expose one of the third peripheral interconnection lines 109c. After simultaneously filling the cell contact hole CH, the third through-via hole TH3, the ground contact hole WCH, and the second through-via hole TH2 with a conductive material, an etch-back or grinding process may be performed to form the cell contact plugs CC, the third through-via TV3, the ground contact plug WC, and the second through-via TV2, simultaneously. This may simplify the process. Subsequently, normal processes may be performed to manufacture the semiconductor memory device 500 of FIGS. 6A to 9.

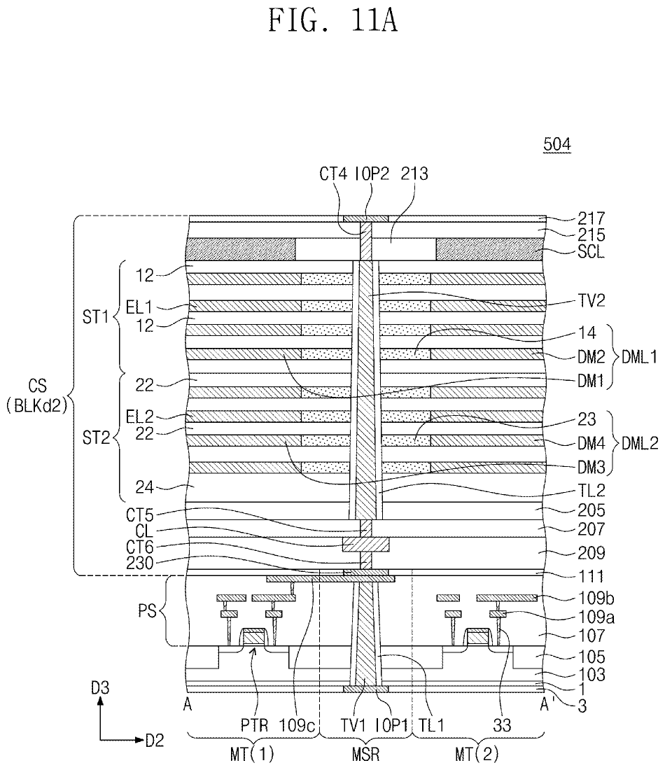

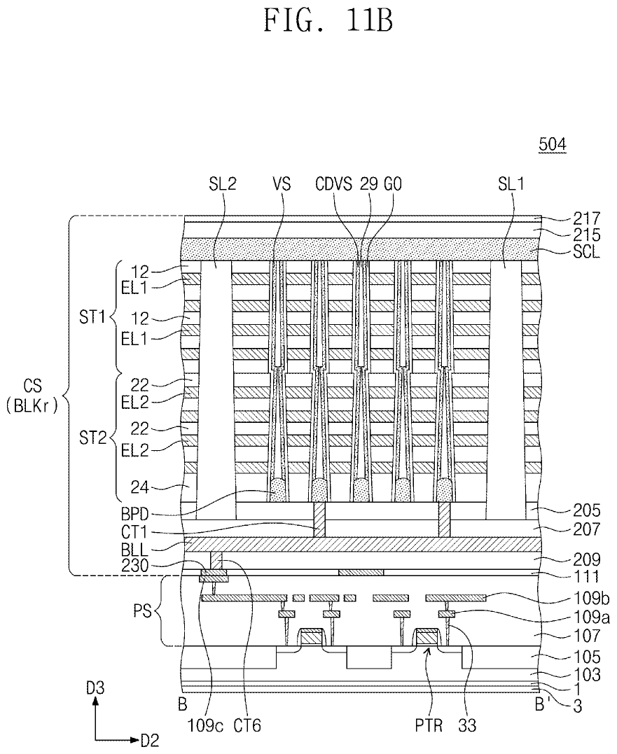

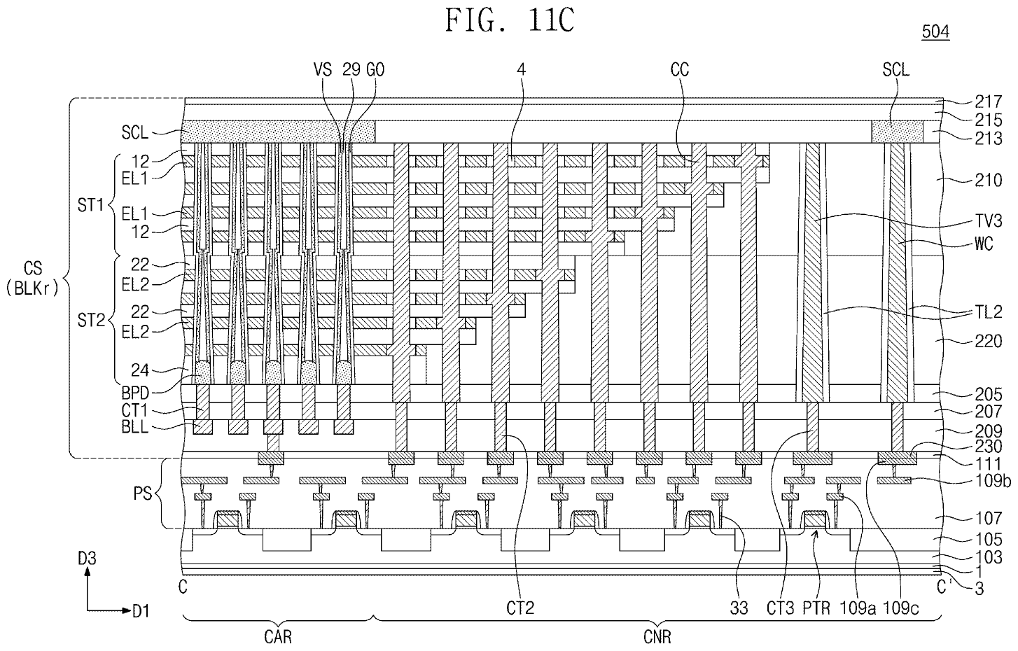

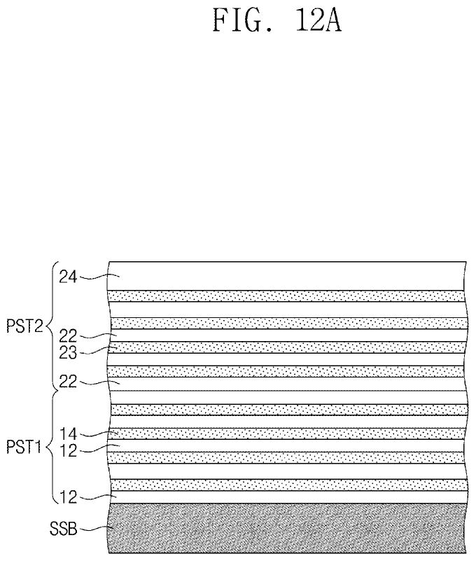

FIG. 11A is a cross-sectional view taken along line A-A′ of FIG. 5A according to some embodiments of the inventive concepts. FIG. 11B is a cross-sectional view taken along line B-B′ of FIG. 5B according to some embodiments of the inventive concepts. FIG. 11C is a cross-sectional view taken along line C-C′ of FIG. 5B according to some embodiments of the inventive concepts.

Referring to FIGS. 11A to 11C, the semiconductor memory device 504 according to the present example may have a structure similar to the cell array structure CS of FIGS. 6A, 7, and 8 turned over and bonded to the peripheral circuit structure PS. In detail, the first stacked structure ST1 is disposed on the second stacked structure ST2. The second through-via TV2 may have a width that increases as the second through-via TV2 goes downward. That is, a width of the second through-via TV2 may increase as it extends toward the peripheral circuit structure PS in the third direction D3. A first upper insulating layer 205, a second upper insulating layer 207, a third upper insulating layer 209, and an interface layer 111 are disposed under the second stacked structure ST2. A fifth contact CT5 penetrates (i.e., extends into) the second upper insulating layer 207 to connect the second through-via TV2 and a connection line CL. A bonding pad 230 is disposed within the interface layer 111. A sixth contact CT6 penetrates (i.e., extends into) the third upper insulating layer 209 to connect the connection line CL and the bonding pad 230. The bonding pad 230 may be in contact with one of the third peripheral interconnection lines 109c on the mat separation region MSR.

The source structure SCL is disposed on the first stacked structure ST1. The source structure SCL may be formed as a single layer of polysilicon layer doped with impurities. The source structure SCL may be in contact with the cell vertical pattern VS. The source structure SCL may be in contact with the ground contact plug WC. The source structure SCL may not be in contact with the second through-via TV2, the cell contact plugs CC, and the third through-via TV3. A side surface of the source structure SCL may be covered with a fifth upper insulating layer 213. A sixth upper insulating layer 215 and a seventh upper insulating layer 217 may be sequentially stacked on the source structure SCL and the fifth upper insulating layer 213. The fourth contact CT4 may penetrate (i.e., extend into) the sixth upper insulating layer 215 and the fifth upper insulating layer 213 to be in contact with the second through-via TV2. A second input/output pad IOP2 may be disposed within the seventh upper insulating layer 217. Other structures may be the same as or similar to those described above.

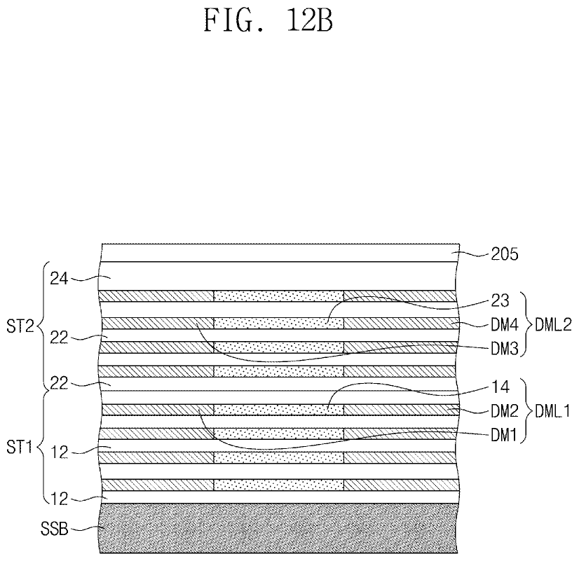

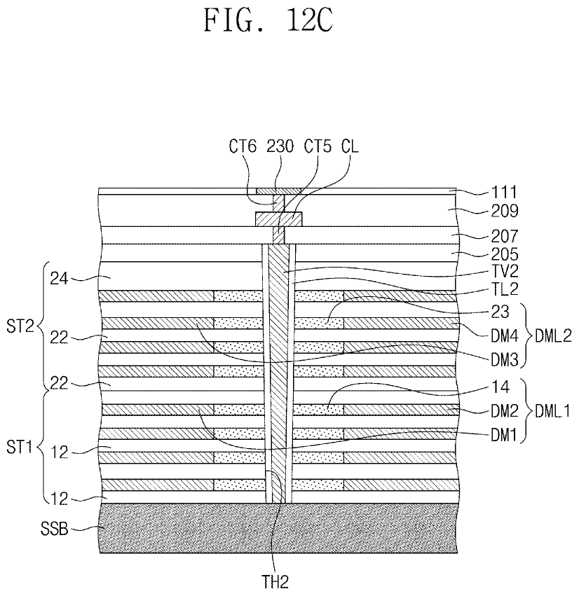

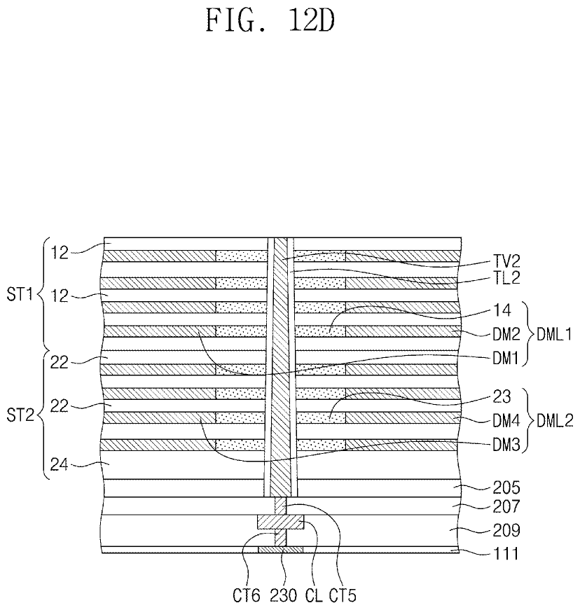

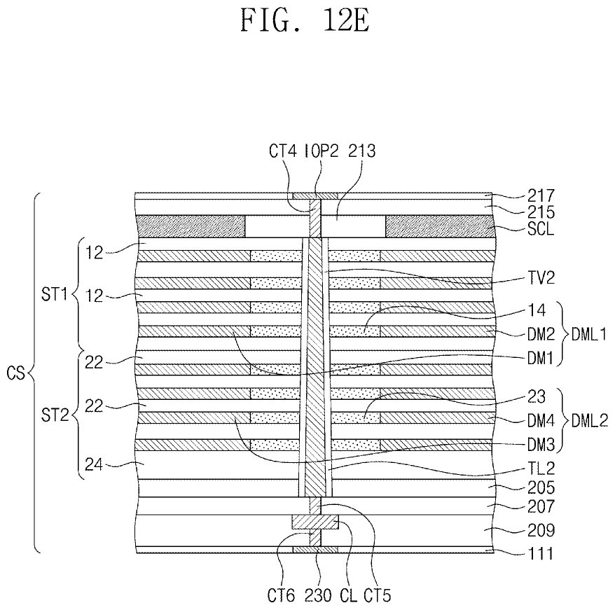

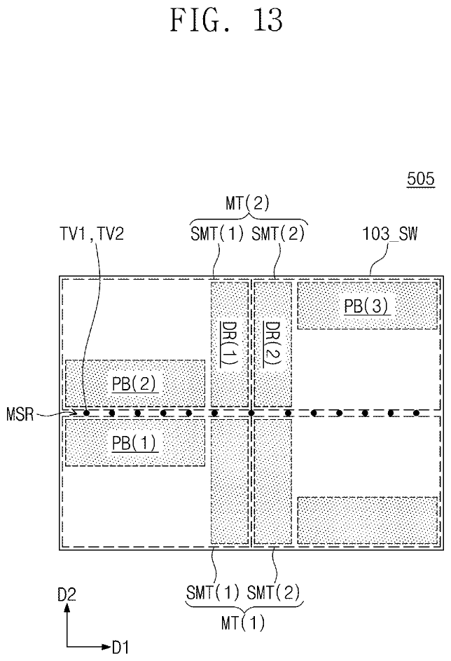

FIGS. 12A to 12E are diagrams illustrating a process of manufacturing the semiconductor memory device of FIG. 11A.

First, a peripheral circuit structure PS is formed on the substrate 103 as described with reference to FIGS. 10A to 10C.

Referring to FIGS. 12A and 11C, the first inter-electrode insulating layers 12 and the first mold insulating layers 14 are alternately and repeatedly deposited on a sacrificial substrate SSB to form a first preliminary stacked structure PST1. By repeatedly performing a trimming process and an anisotropic etching process, end portions of the first inter-electrode insulating layers 12 and the first mold insulating layers 14 in the connection region CNR may be formed into a staircase shape (i.e., a stepped profile). A first flat insulating layer 210 is formed and a chemical mechanical polishing (CMP) process is performed to cover the ends of the first preliminary stacked structure PST1. In the cell region CAR, a portion of the first preliminary stacked structure PST1 is etched to form lower holes and the lower holes are filled with a sacrificial material to form first sacrificial patterns. The first sacrificial patterns may be formed to define the positions of the cell vertical patterns VS of FIGS. 5A and 5B. The second inter-electrode insulating layers 22 and 24 and the second mold

insulating layers 23 are alternately and repeatedly deposited on the first preliminary stacked structure PST1 and the first flat insulating layer 210 to form a second preliminary stacked structure PST2. The second inter-electrode insulating layers 22 and 24 may include the same material as the first inter-electrode insulating layers 12. The second mold insulating layers 23 may include the same material as the first mold insulating layers 14. By repeatedly performing the trimming process and the anisotropic etching process, end portions of the second inter-electrode insulating layers 22 and 24 and the second mold insulating layers 23 in the connection region CNR may be formed into a staircase shape (i.e., a stepped profile). A second flat insulating layer 220 is formed and a chemical mechanical polishing (CMP) process is performed to cover the ends of the second preliminary stacked structure PST2. Additionally, the second preliminary stacked structure PST2 may be etched in the cell region CAR to form upper holes exposing the first sacrificial patterns, respectively.

The first sacrificial patterns may be removed through the upper holes to expose lower holes. The upper holes and the lower holes that overlap each other may constitute vertical holes. As illustrated in FIG. 7, a gate insulating layer GO, a cell vertical pattern VS, a buried insulating pattern 29, and bit line pads BPD may be formed in the vertical holes, respectively. Referring to FIGS. 7 and 10E, a first upper insulating layer 205 is formed on the second preliminary stacked structure PST2. The first upper insulating layer 205, the second preliminary stacked structure PST2, and the first preliminary stacked structure PST1 are etched to form first grooves G1 and second grooves G2. As illustrated in FIG. 4, the second groove G2 is not formed in the second dummy block BLKd2.

Referring to FIGS. 7, 10E, and 12B, the second buffer layer 18, the first sacrificial layer 17, and the first buffer layer 16 may be removed through the first and second grooves G1 and G2 to form a first empty space. An etchant may be supplied through the first and second grooves G1 and G2 and may remove the first mold insulating layers 14 and the second mold insulating layers 23 to form second empty spaces between the inter-electrode insulating layers 12, 22, and 24. A first conductive layer is conformally deposited to fill the second empty spaces through the first and second grooves G1 and G2. Then, an anisotropic etching process may be performed to remove the first conductive layer in the first and second grooves G1 and G2 to form electrode layers EL1 and EL2 in the second empty spaces. As a result, the first stacked structure ST1 and the second stacked structure ST2 may be formed. Before depositing the first conductive layer, the high dielectric layer HL illustrated in FIG. 9 may be conformally formed. As illustrated in FIG. 4, as the second dummy block BLKd2 does not have a second groove G2 and the etchant is supplied only through the first groove G1, all of the first mold insulating layers 14 and the second mold insulating layers 23 are not removed and some remain on the mat separation region MSR as illustrated in FIG. 12B due to limitations in the etchant penetration length.

Referring to FIGS. 7 and 12C, an insulating layer may be conformally deposited and anisotropically etched to form a block separation pattern SL1 and a central separation pattern SL2 that fill the first and second grooves G1 and G2, respectively.

Referring to FIGS. 8, 10G, and 12C, in the connection region CNR, a cell contact hole CH for a cell contact plug CC, a third through-via hole TH3 for a third through-via TV3, a ground contact hole WCH for a ground contact plug WC are formed. Additionally, a second through-via hole TH2 is formed on the mat separation region MSR to expose one of the third peripheral interconnection lines 109c. After simultaneously filling the cell contact hole CH, the third through-via hole TH3, the ground contact hole WCH, and the second through-via hole TH2 with a conductive material, an etch-back or grinding process is performed to form cell contact plugs CC, the third through-via TV3, the ground contact plug WC, and the second through-via TV2, simultaneously.

Referring to FIG. 12C, a second upper insulating layer 207, a fifth contact CT5, a connection line CL, a third upper insulating layer 209, a sixth contact CT6, an interface layer 111, and a bonding pad 230 are formed on the first upper insulating layer 205.

Referring to FIG. 12D, after the structure of FIG. 12C is turned over, a sacrificial substrate SSB is removed and the first inter-electrode insulating layer 12 of the first stacked structure ST1 is exposed.

Referring to FIG. 12E, a source structure SCL, a fifth upper insulating layer 213, a sixth upper insulating layer 215, a fourth contact CT4, a seventh upper insulating layer 217 and a second input/output pad IOP2 are formed on the first stacked structure ST1. Accordingly, the cell array structure CS may be formed.

Referring again to FIGS. 11A to 11C, the cell array structure CS of FIG. 12E is bonded to the peripheral circuit structure PS of FIG. 10C.

FIG. 13 is a plan view of a semiconductor memory device according to some embodiments of the inventive concepts.

Referring to FIG. 13, a semiconductor memory device 505 according to the present example has two mat regions MT. That is, the semiconductor memory device 505 according to the present example may include first and second mat regions MT(1) and MT(2). The mat separation region MSR may have a line shape extending in the first direction D1. Other structures may be the same as or similar to those described above.

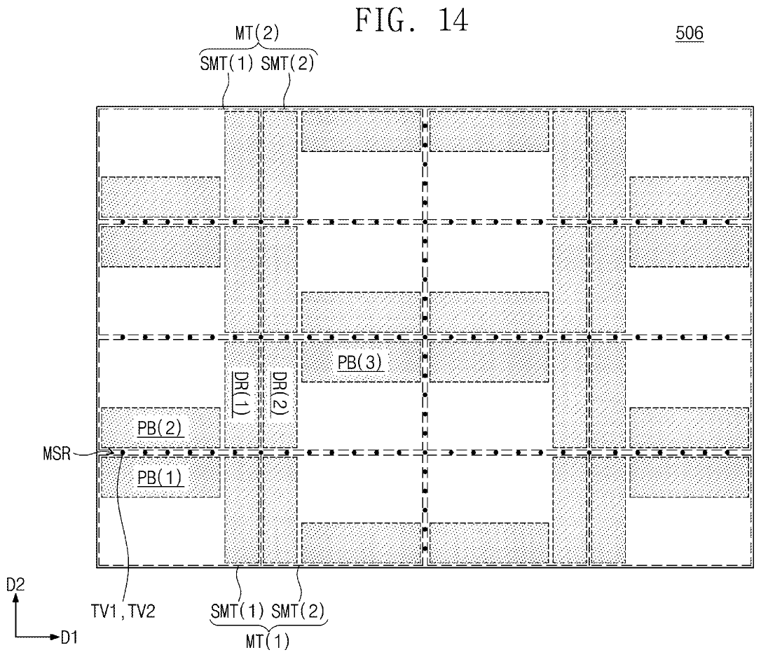

FIG. 14 is a plan view of a semiconductor memory device according to some embodiments of the inventive concepts.

Referring to FIG. 14, a semiconductor memory device 506 according to the present example has eight mat regions MT. The mat regions MT may be arranged in the first direction D1 and the second direction D2. The mat separation region MSR may have a grid shape when viewed from a plan view. The structures of the peripheral circuit structures PS on the mat regions MT may have a mirror symmetrical shape in the first direction D1 or the second direction D2. Other structures may be the same as or similar to those described above.

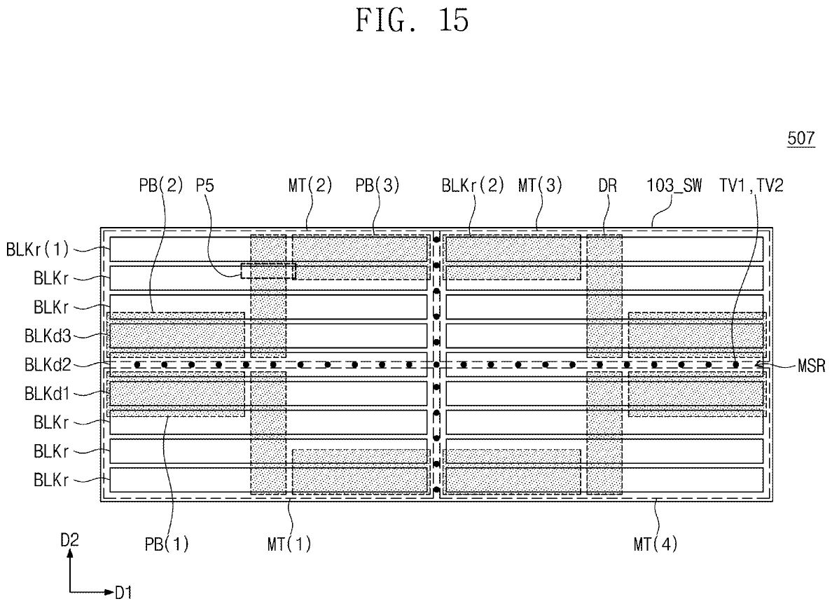

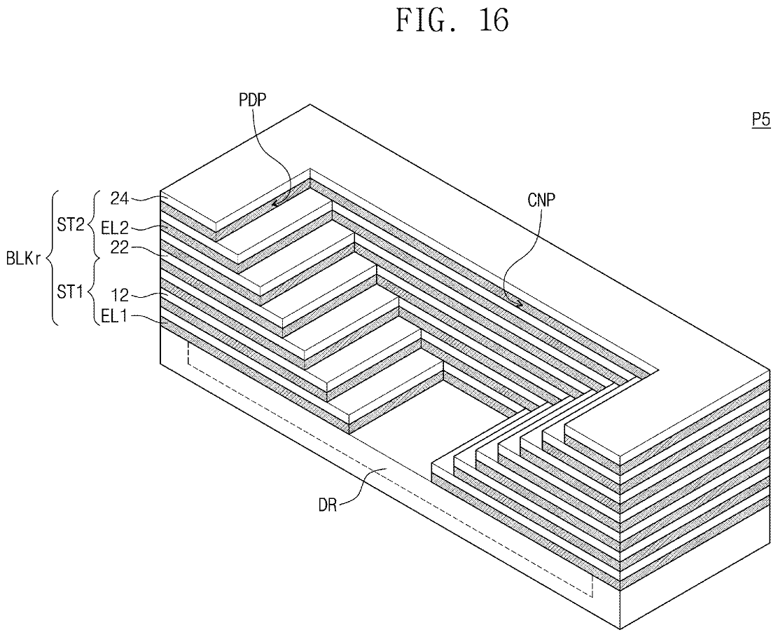

FIG. 15 is a plan view of a semiconductor memory device according to some embodiments of the inventive concepts. FIG. 16 is an enlarged perspective view of portion ‘P5’ of FIG. 15.

Referring to FIGS. 15 and 16, in a semiconductor memory device 507 according to the present example, one decoder region DR is disposed on a center of the mat region MT. That is, one decoder region DR is disposed on a center portion of the mat region MT. Blocks BLKr, BLKd1 to BLKd3 may cross one mat region MT. The centers of the blocks BLKr, BLKd1 to BLKd3 may overlap the decoder region DR. That is, the respective center portions of the blocks BLKr, BLKd1 and BLKd3 may overlap the decoder region DR. The electrode layers EL1 and EL2 of the blocks BLKr and BLKd1 to BLKd3 may each have a pad portion PDP and a connection portion CNP (also referred to as a pad connection portion CNP) on the decoder region DR. The pad portions PDP of the electrode layers EL1 and EL2 may have a staircase shape (i.e., a stepped profile). The connection portion CNP may connect pad portions PDP adjacent to each other at the same level (i.e., adjacent to each other at the same height). Accordingly, the electrode layers EL1 and EL2 each have the same electric potential in one mat region MT. Although not illustrated, cell contact plugs CC may be connected to the pad portions PDP, respectively, as described with reference to FIG. 8 or 11C. In the inventive concepts, due to this structure, the region occupied by the decoder region DR in one mat region MT may be reduced, thereby reducing the horizontal size of the semiconductor memory device. Other structures may be the same as or similar to those described above.

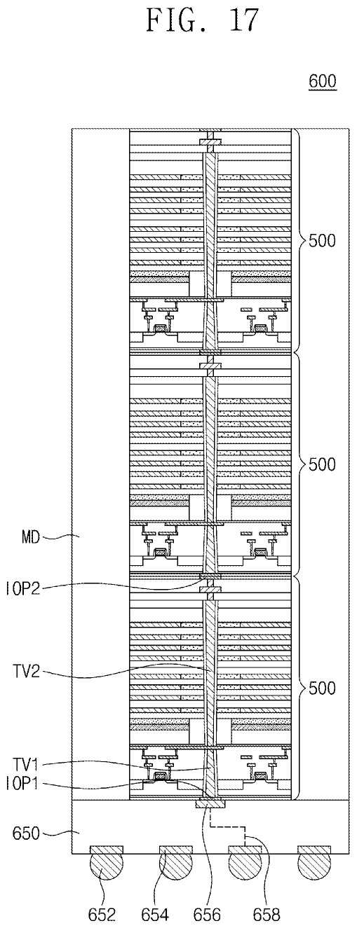

FIG. 17 is a cross-sectional view of a semiconductor package according to some embodiments of the inventive concepts.

Referring to FIG. 17, a semiconductor package 600 according to the present example includes a plurality of semiconductor memory devices 500 sequentially stacked on a package substrate 650. In this specification, ‘semiconductor memory device’ may also be referred to as ‘semiconductor die’ or ‘semiconductor chip’. The semiconductor memory devices 500 may be the same as or similar to those described with reference to FIGS. 2A to 9.

The package substrate 650 may be a printed circuit board, a redistribution substrate, or an interposer substrate. Alternatively, the package substrate 650 may be replaced with a buffer die or logic die. The package substrate 650 may include an upper conductive pattern 656 disposed on an upper surface thereof, lower conductive patterns 654 disposed on a lower surface thereof, and internal interconnection lines 658 connecting them. External connection members 652 are bonded to the lower conductive patterns 654. The external connection members 652 may be conductive bumps, conductive pillars, or solder balls. Sidewalls of the semiconductor memory devices 500 and an upper surface of the package substrate 650 may be covered with a mold layer MD.

The first input/output pad IOP1 of the semiconductor memory device 500 disposed at the lowermost level may be in direct contact with the upper conductive pattern 656 of the package substrate 650. The second input/output pad IOP2 of the semiconductor memory device 500 disposed at the lowermost level is in contact with the first input/output pad IOP1 of the semiconductor memory device 500 disposed thereabove. Due to this structure, in the semiconductor package 600 according to the inventive concepts, a connection length between the semiconductor memory devices 500 may be shortened, thereby improving signal transmission speed. Additionally, the semiconductor memory devices 500 may be vertically stacked and side surfaces thereof may be aligned with each other, and thus a horizontal size of the semiconductor package 600 may be reduced. Accordingly, a highly integrated semiconductor package may be provided.

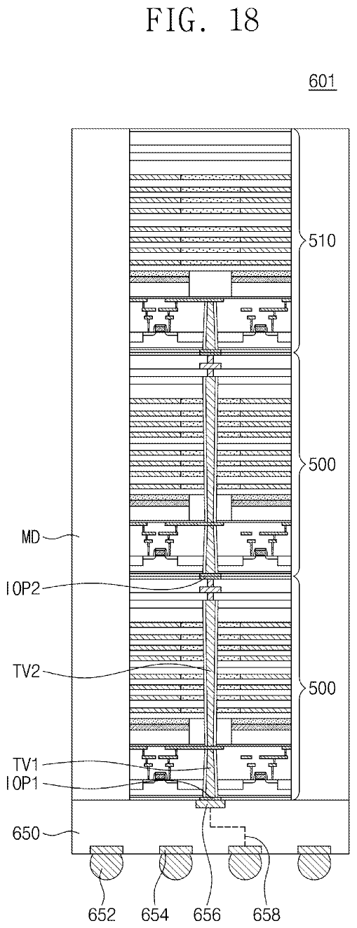

FIG. 18 is a cross-sectional view of a semiconductor package according to some embodiments of the inventive concepts.

Referring to FIG. 18, a semiconductor package 601 according to the present example has the same structure as that of FIG. 17, but the semiconductor memory device 510 disposed at the uppermost level may exclude the second through-via TV2. Other structures may be the same as or similar to FIG. 17.

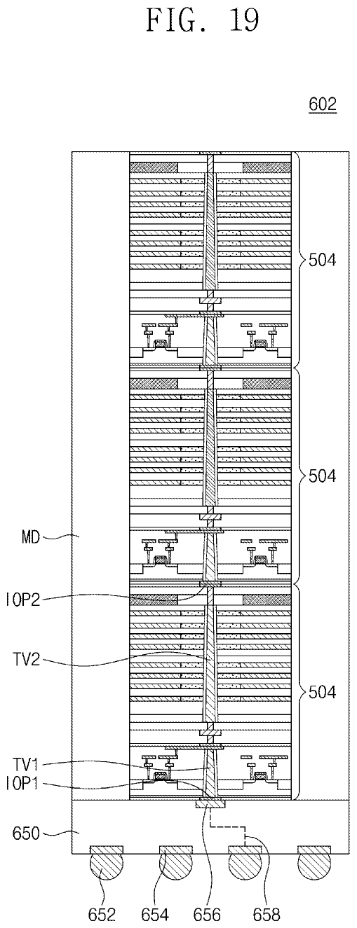

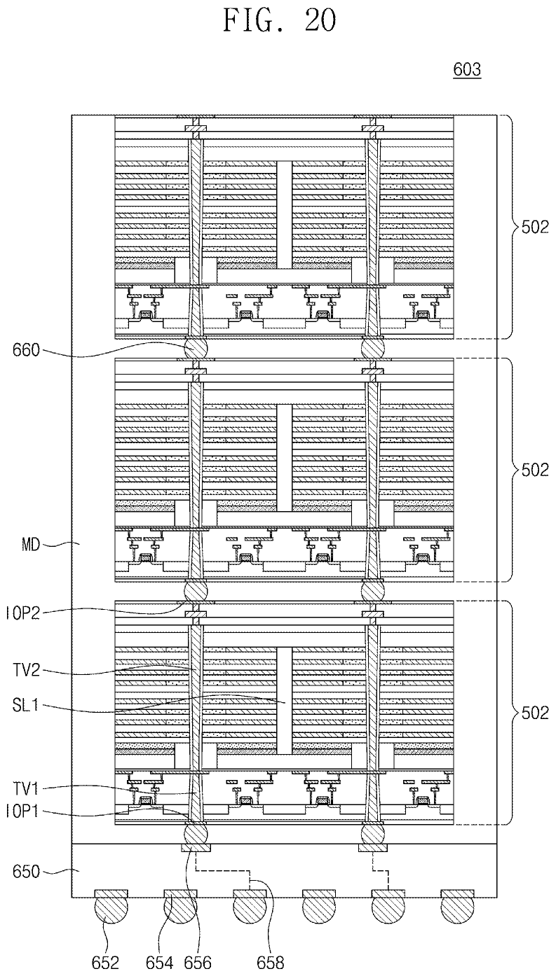

FIG. 19 is a cross-sectional view of a semiconductor package according to some embodiments of the inventive concepts.

Referring to FIG. 19, a semiconductor package 602 according to the present example includes a plurality of semiconductor memory devices 504 sequentially stacked on a package substrate 650. The semiconductor memory devices 504 may be the same as or similar to those described with reference to FIGS. 11A to 11C. Other structures may be the same as or similar to FIG. 17.

FIG. 20 is a cross-sectional view of a semiconductor package according to some embodiments of the inventive concepts.

Referring to FIG. 20, a semiconductor package 603 according to the present example includes a plurality of semiconductor memory devices 502 sequentially stacked on a package substrate 650. The semiconductor memory devices 502 may be the same as or similar to those described with reference to FIGS. 2A to 9 (particularly, FIG. 6C). The package substrate 650 may be a printed circuit board, a redistribution substrate, or an interposer substrate. Alternatively, the package substrate 650 may be replaced with a buffer die or logic die. The package substrate 650 may include an upper conductive pattern 656 disposed on an upper surface thereof, lower conductive patterns 654 disposed on a lower surface thereof, and internal interconnection lines 658 connecting them. External connection members 652 are bonded to the lower conductive patterns 654. The external connection members 652 may be conductive bumps, conductive pillars, or solder balls. Sidewalls of the semiconductor memory devices 502 and an upper surface of the package substrate 650 may be covered with a mold layer MD.

Internal connection members 660 may be interposed between the package substrate 650 and the semiconductor memory devices 502. One of the internal connection members 660 may be interposed between the first input/output pad IOP1 of the semiconductor memory device 502 disposed at the lowermost level and the upper conductive pattern 656 of the package substrate 650. Another one of the internal connection members 660 may be interposed between the second input/output pad IOP2 of the semiconductor memory device 502 disposed at the lowermost level and the first input/output pad IOP1 of the semiconductor memory device 502 disposed thereabove. The internal connection members 660 may be conductive bumps, conductive pillars, or solder balls. Although not illustrated, an underfill layer may be interposed between the package substrate 650 and the semiconductor memory devices 502.

In the semiconductor memory device and the electronic system including the same according to the inventive concepts, the through-vias and the input/output pads may be disposed on the mat separation region, thereby reducing the overall horizontal size of the semiconductor memory device. As a result, the highly integrated semiconductor memory device and the electronic system including the same may be provided.

Additionally, in the semiconductor package according to the inventive concepts, the semiconductor dies may be stacked such that the input/output pads of the semiconductor dies are in contact with each other, thereby improving the signal transmission speed and reducing the horizontal size of the semiconductor package. As a result, the highly integrated semiconductor package with the improved operating speed may be provided.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. It will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of inventive concepts.

While example embodiments are described above, a person skilled in the art will understand that many modifications and variations may be made without departing from the scope of the inventive concepts defined in the following claims. Accordingly, the example embodiments of the inventive concepts should be considered in all respects as illustrative and not restrictive, with the scope of the inventive concepts being indicated by the appended claims. The embodiments of FIGS. 1A through 20 can be combined with each other.

What is claimed is:

1. A semiconductor memory device comprising:
a substrate including a plurality of mat regions and a mat separation region between ones of the mat regions;
a peripheral circuit structure on the substrate and including peripheral circuits;
a cell array structure on the peripheral circuit structure;
a first through-via extending into the substrate in the mat separation region; and
a second through-via extending into the cell array structure on the mat separation region and electrically connected to the first through-via,
wherein the second through-via overlaps the first through-via in a plan view.

2. The semiconductor memory device of claim 1, wherein the cell array structure comprises:
a plurality of memory blocks on at least one of the mat regions; and
a dummy block on the mat separation region,
wherein the second through-via extends into the dummy block.

3. The semiconductor memory device of claim 2, wherein the dummy block comprises:
inter-electrode insulating layers that are sequentially stacked; and
dummy electrode layers respectively between the inter-electrode insulating layers,
wherein each of the dummy electrode layers comprises:
a first dummy electrode and a second dummy electrode spaced apart from each other; and
a mold insulating layer between the first dummy electrode and the second dummy electrode, and
wherein the second through-via extends into the mold insulating layer and the inter-electrode insulating layers.

4. The semiconductor memory device of claim 1, wherein the mat regions include first and second mat regions arranged in a first direction,
wherein the peripheral circuit structure comprises:
a first page buffer region on the first mat region and adjacent to the second mat region; and
a second page buffer region on the second mat region and adjacent to the first mat region, and
wherein the mat separation region is between the first page buffer region and the second page buffer region.

5. The semiconductor memory device of claim 4, wherein the first mat region includes a first sub-mat region and a second sub-mat region that are adjacent to each other in a second direction intersecting the first direction,
wherein the peripheral circuit structure comprises:
a first decoder region on the first sub-mat region and adjacent to the second sub-mat region; and
a second decoder region on the second sub-mat region and adjacent to the first sub-mat region,
wherein the cell array structure comprises:
first blocks on the first sub-mat region and spaced apart from each other in the first direction; and
second blocks on the second sub-mat region and spaced apart from each other in the first direction,
wherein end portions of the first blocks have a stepped profile on the first decoder region, and
wherein end portions of the second blocks have a stepped profile on the second decoder region.

6. The semiconductor memory device of claim 4, wherein the peripheral circuit structure comprises:
a first decoder region on a center portion of the first mat region; and
a second decoder region on a center portion of the second mat region,
wherein the cell array structure comprises:
first blocks on the first mat region and spaced apart from each other in the first direction; and
second blocks on the second mat region and spaced apart from each other in the first direction,
wherein respective center portions of the first blocks overlap the first decoder region,
wherein respective center portions of the second blocks overlap the second decoder region,
wherein each of the first blocks includes alternately stacked first electrode layers and first inter-electrode insulating layers, and
wherein each of the first electrode layers includes a pad portion and a pad connection portion on the first decoder region.

7. The semiconductor memory device of claim 1, wherein the mat regions include first and second mat regions arranged in a first direction,
wherein the first mat region includes a first sub-mat region and a second sub-mat region that are adjacent to each other in a second direction intersecting the first direction, and
wherein the peripheral circuit structure comprises:
a first page buffer region on the first sub-mat region and adjacent to the mat separation region; and
a second page buffer region on the second sub-mat region and adjacent to a sidewall of the substrate.

8. The semiconductor memory device of claim 1, further comprising:
a first input/output pad on a lower surface of the substrate and electrically connected to the first through-via; and
a second input/output pad on an upper portion of the cell array structure and electrically connected to the second through-via,
wherein a width of the first input/output pad is different from a width of the second input/output pad.

9. The semiconductor memory device of claim 1, wherein the peripheral circuit structure comprises:
transistors on the substrate;
a first interlayer insulating layer on the transistors;
a first etch stop layer on the first interlayer insulating layer;
a second interlayer insulating layer on the first etch stop layer;
a second etch stop layer on the second interlayer insulating layer; and
a mat separation insulating layer extending into the second etch stop layer, the second interlayer insulating layer, the first etch stop layer, and the first interlayer insulating layer on the mat separation region and adjacent to the substrate, and
wherein the first through-via extends into the mat separation insulating layer.

10. The semiconductor memory device of claim 9, wherein the peripheral circuit structure further comprises:
a first peripheral interconnection line on the first etch stop layer; and
a second peripheral interconnection line on the second etch stop layer, and
wherein the second through-via is in contact with the second peripheral interconnection line.

11. A semiconductor package comprising:
a package substrate;
semiconductor dies sequentially stacked on the package substrate; and
a mold layer on side surfaces of the semiconductor dies and an upper surface of the package substrate,
wherein each of the semiconductor dies comprises:
a substrate including a plurality of mat regions and a mat separation region between ones of the mat regions;
a peripheral circuit structure on the substrate and including peripheral circuits;
a cell array structure on the peripheral circuit structure;
a first through-via extending into the substrate in the mat separation region;
a first input/output pad on a lower surface of the first through-via;
a second through-via extending into the cell array structure on the mat separation region and electrically connected to the first through-via; and
a second input/output pad on the second through-via,
wherein the second through-via overlaps the first through-via,
wherein the second input/output pad of a first one of the semiconductor dies is in contact with the first input/output pad of a second one of the semiconductor dies, and
wherein the second one of the semiconductor dies is on the first one of the semiconductor dies.

12. The semiconductor package of claim 11, wherein the cell array structure comprises:
a plurality of memory blocks on at least one of the mat regions; and
a dummy block on the mat separation region, and
wherein the second through-via extends into the dummy block.

13. The semiconductor package of claim 12, wherein the dummy block comprises:
inter-electrode insulating layers that are sequentially stacked; and
dummy electrode layers respectively between the inter-electrode insulating layers,
wherein each of the dummy electrode layers comprises:
a first dummy electrode and a second dummy electrode spaced apart from each other; and
a mold insulating layer between the first dummy electrode and the second dummy electrode, and
wherein the second through-via extends into the mold insulating layer and the inter-electrode insulating layers.

14. The semiconductor package of claim 11, wherein the mat regions include first and second mat regions arranged in a first direction,
wherein the peripheral circuit structure comprises:
a first page buffer region on the first mat region and adjacent to the second mat region; and
a second page buffer region on the second mat region and adjacent to the first mat region, and
wherein the mat separation region is between the first page buffer region and the second page buffer region.

15. The semiconductor package of claim 14, wherein the first mat region includes a first sub-mat region and a second sub-mat region that are adjacent to each other in a second direction intersecting the first direction,
wherein the peripheral circuit structure comprises:
a first decoder region on the first sub-mat region and adjacent to the second sub-mat region; and
a second decoder region on the second sub-mat region and adjacent to the first sub-mat region,
wherein the cell array structure comprises:
first blocks on the first sub-mat region and spaced apart from each other in the first direction; and
second blocks on the second sub-mat region and spaced apart from each other in the first direction,
wherein end portions of the first blocks have a stepped profile on the first decoder region, and
wherein end portions of the second blocks have a stepped profile on the second decoder region.

16. The semiconductor package of claim 14, wherein the peripheral circuit structure comprises:
a first decoder region on a center portion of the first mat region; and
a second decoder region on a center portion of the second mat region,
wherein the cell array structure comprises:
first blocks on the first mat region and spaced apart from each other in the first direction; and
second blocks on the second mat region and spaced apart from each other in the first direction,
wherein respective center portions of the first blocks overlap the first decoder region,
wherein respective center portions of the second blocks overlap the second decoder region,
wherein each of the first blocks includes alternately stacked first electrode layers and first inter-electrode insulating layers, and
wherein each of the first electrode layers includes a pad portion and a pad connection portion on the first decoder region.

17. The semiconductor package of claim 11, wherein the mat regions include first and second mat regions arranged in a first direction,
wherein the first mat region includes a first sub-mat region and a second sub-mat region that are adjacent to each other in a second direction intersecting the first direction, and
wherein the peripheral circuit structure comprises:
a first page buffer region on the first sub-mat region and adjacent to the mat separation region; and
a second page buffer region on the second sub-mat region and adjacent to a sidewall of the substrate.

18. The semiconductor package of claim 11, wherein the first input/output pad is on a lower surface of the substrate and is electrically connected to the first through-via,
wherein the second input/output pad is on an upper portion of the cell array structure and is electrically connected to the second through-via, and
wherein a width of the first input/output pad is different from a width of the second input/output pad.

19. The semiconductor package of claim 11, wherein the peripheral circuit structure comprises:
transistors on the substrate;
a first interlayer insulating layer on the transistors;
a first etch stop layer on the first interlayer insulating layer;
a second interlayer insulating layer on the first etch stop layer;
a second etch stop layer on the second interlayer insulating layer; and
a mat separation insulating layer extending into the second etch stop layer, the second interlayer insulating layer, the first etch stop layer, and the first interlayer insulating layer on the mat separation region and adjacent to the substrate, and
wherein the first through-via extends into the mat separation insulating layer.

20. An electronic system comprising:
a semiconductor memory device; and
a controller electrically connected to the semiconductor memory device through an input/output pad and configured to control the semiconductor memory device, wherein the semiconductor memory device comprises:
a substrate including a plurality of mat regions and a mat separation region between ones of the mat regions;
a peripheral circuit structure on the substrate and including peripheral circuits;
a cell array structure on the peripheral circuit structure;
a first through-via extending into the substrate in the mat separation region; and
a second through-via extending into the cell array structure on the mat separation region and electrically connected to the first through-via, and
wherein the second through-via overlaps the first through-via.
